(19) United States
(12) Patent Application Publication
(10) Pub. No.: US 2025/0147492 A1
(43) Pub. Date: May 8, 2025

(54) COMPONENT MOUNTING SYSTEM

(71) Applicant: YAMAHA HATSUDOKI KABUSHIKI KAISHA, Iwata-shi, Shizuoka (JP)

(72) Inventor: Hidekazu SHIMIZU, Shizuoka (JP)

(73) Assignee: YAMAHA HATSUDOKI KABUSHIKI KAISHA, Iwata-shi, Shizuoka (JP)

(21) Appl. No.: 18/690,977

(22) PCT Filed: Sep. 17, 2021
(86) PCT No.: PCT/JP2021/034265

§ 371 Date: Mar. 11, 2024

(51) Int. Cl. G05B 19/418

(52) U.S. Cl. CPC G05B 19/41865; G05B 2219/45026

(57) ABSTRACT

A management device of a component mounting system includes a management storage unit, a calculation unit, and a data generating unit. The management storage unit stores management data in which processing state data is associated with each piece of production factor information that identifies each production factor used in production of a component loading board. The calculation unit calculates normal processing rate data of normal suction rate data or normal loading rate data based on a data group of the management data from a prescribed time point to a current time point. The calculation unit outputs a normal processing rate data set indicating a data group of the normal processing rate data for each use time point. The data generating unit generates predicted normal processing rate data subsequent to the current time point according to a change in a use variable based on the normal processing rate data set.

### CROSS-REFERENCE TO RELATED APPLICATION

This application claims benefit of priority to International Patent Application No. PCT/JP2021/034265, filed Sep. 17, 2021, the entire contents of which are incorporated herein by reference.

### BACKGROUND

### Technical Field

The present disclosure relates to a component mounting system equipped with a mounting machine that produces a component loading board with components loaded.

### Background Art

Conventionally, a component mounting system has been known that is equipped with a mounting machine that obtains a component loading board by loading electronic components (hereinafter simply referred to as “component”) on a board such as a printed circuit board. In this kind of component mounting system, the mounting machine includes a feeder that supplies the component, and a suction nozzle that suctions the component supplied by the feeder to load the suctioned component on the board.

In the component mounting system, the processing state may become abnormal (error), such as the component suction state by the suction nozzle or the component loading state on the component loading board, and an error may occur. When such an error occurs, the error affects the quality of the component loading board. Therefore, in each production factor such as the feeder and the suction nozzle used in the production of the component loading board, measures are taken such as predicting in advance the production factor that can become the error generating factor and executing maintenance for the production factor such that the occurrence of error can be suppressed.

Japanese Patent Application Laid-Open No. 2019-62163 discloses a technology for detecting malfunctions in production factors (devices) such as the feeder and the suction nozzle. The technology disclosed in Japanese Patent Application Laid-Open No. 2019-62163 collects data including information about errors in the mounting machine and determines whether the trend of feature data such as the number of errors of suction error in the collected data deviates from the normal trend. If the trend of the feature data deviates from the normal trend, a malfunction in the production factor is detected.

The technology disclosed in Japanese Patent Application Laid-Open No. 2019-62163 only detects the malfunction in the production factor every time the production factor is used during the production of the component loading board in the mounting machine. Therefore, it is not possible to predict the future error generating status subsequent to the current time point according to the use of the production factor. In this case, it is difficult to take appropriate measures such as maintenance to suppress the error generation in the future subsequent to the current time point, and there is room for improvement in this respect.

### SUMMARY

Accordingly, the present disclosure provides a component mounting system that can predict the future error generating status subsequent to the current time point according to the use of the production factor used in the production of the component loading board.

A component mounting system according to one aspect of the present disclosure includes a mounting machine that produces a component loading board on which a component is loaded, and a management device that manages the production of the component loading board in the mounting machine. The mounting machine includes a feeder that supplies the component and a holding member that holds the component supplied by the feeder and obtains the component loading board by loading the held component on a board. The management device includes a storage unit, a calculation unit, a data generating unit, an operating unit, and a display unit. The storage unit is configured to accumulate and store, for each use of production factors, management data in which processing state data indicating whether a processing state indicated by at least one of a holding state of the component by the holding member and a loading state of the component on the component loading board is normal or abnormal is associated with each piece of production factor information for identifying the production factors indicating the feeder and the holding member used in the production of the component loading board. The calculation unit is configured to calculate normal processing rate data indicating a ratio of a number of uses when the processing state is normal to a number of uses of the production factors based on a data group of the management data within a period from a prescribed time point to a current time point for each of use time points when the production factors are used within the period, and output a normal processing rate data set with a data group of the normal processing rate data for each of the use time points as one set, in association with each piece of the production factor information. The data generating unit is configured to generate predicted normal processing rate data indicating a predicted value of the normal processing rate data subsequent to the current time point according to a change in a use variable indicated by at least one of use time and the number of uses of the production factors in association with each piece of the production factor information, based on the normal processing rate data set. Various commands are input into the operating unit. The display unit is configured to display the predicted normal processing rate data associated with the production factor information corresponding to each of the production factors indicated by a factor selection command when the factor selection command to select one of the production factors is input via the operating unit.

The object, features, and advantages of the present disclosure will be more apparent from the following detailed description and the accompanying drawings.

### BRIEF DESCRIPTION OF THE DRAWINGS

FIG. 1 is a diagram showing an overall configuration of a component mounting system according to one embodiment of the present disclosure;

FIG. 2 is a block diagram of a mounting machine provided in the component mounting system;

FIG. 3 is a plan view showing a configuration of a mounting machine body in the mounting machine;

FIG. 4 is an enlarged view of a portion of a head unit of the mounting machine body;

FIG. 5 is a block diagram of a management device provided in the component mounting system;

FIG. 6 is a view showing a display screen of a display unit in the management device, showing a state when a suction nozzle is selected as a production factor and the number of uses is selected as a use variable;

FIG. 7 is a view showing a display screen of the display unit in the management device, showing a state when a feeder is selected as the production factor and the number of uses is selected as the use variable;

FIG. 8 is a view showing a display screen of the display unit in the management device, showing a state when the suction nozzle is selected as the production factor and the use time is selected as the use variable;

FIG. 9 is a view showing a display screen of the display unit in the management device, showing a state when the feeder is selected as the production factor and the use time is selected as the use variable;

FIG. 10 is a view showing a display screen of the display unit in the management device, showing a state when a command to set a narrowing condition is input via an operating unit;

FIG. 11 is a view showing a display screen of the display unit in the management device, showing a state when a command to select a unique normal processing rate data from a data group of normal processing rate data that constitutes normal processing rate distribution is input via the operating unit;

FIG. 12 is a view showing a display screen of the display unit in the management device, showing a state when an error type selection command is input via the operating unit;

FIG. 13 is a view showing a display screen of the display unit in the management device, showing a state when the number of uses is selected as the use variable and a command to display a regression equation is input via the operating unit;

FIG. 14 is a view showing a display screen of the display unit in the management device, showing a state when the use time is selected as the use variable and the command to display the regression equation is input via the operating unit;

FIG. 15 is a view showing a display screen of the display unit in the management device, showing a state when a command to output notification information is input via the operating unit; and

FIG. 16 is a view showing a state in which the notification information output from the management device is displayed on a portable terminal.

### DETAILED DESCRIPTION

A component mounting system according to an embodiment of the present disclosure will be described below with reference to the drawings.

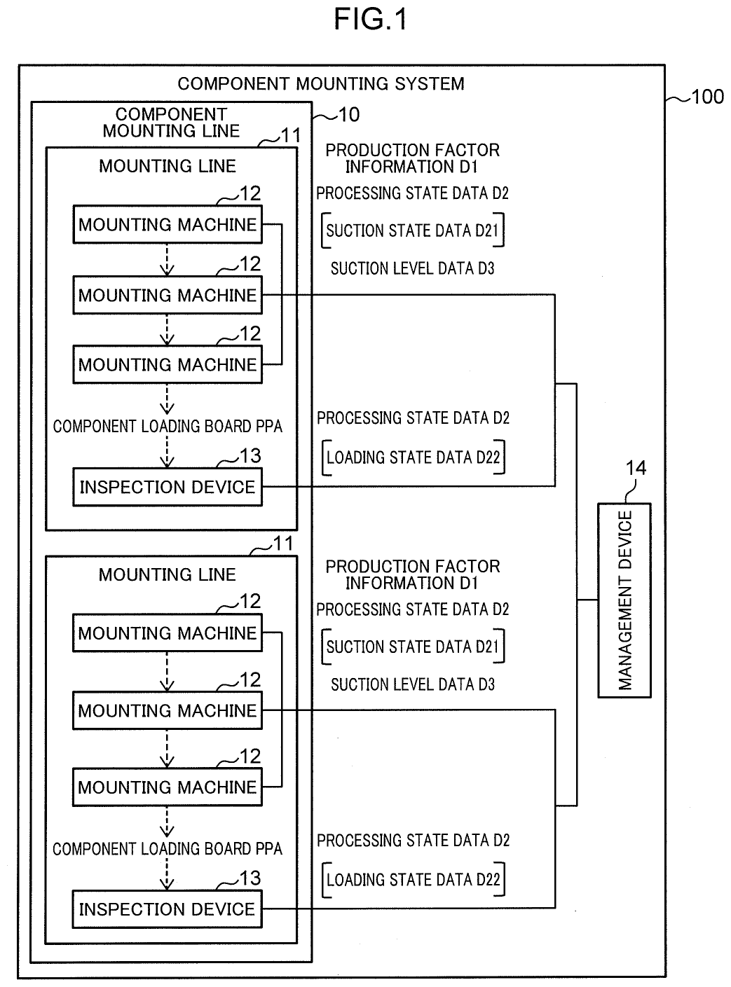

As shown in FIG. 1, a component mounting system 100 according to the present embodiment includes a component mounting line 10 and a management device 14.

The component mounting line 10 includes a plurality of mounting lines 11 including at least mounting machines 12 that each produce a component loading board PPA on which a component is loaded. In each mounting line 11 that constitutes the component mounting line 10, the plurality of mounting machines 12 and an inspection device 13 are connected in a straight line. The management device 14 is a device for managing the production of the component loading board PPA in the mounting machines 12. The management device 14 is connected to the mounting machines 12 and the inspection devices 13 in a way that allows data communication.

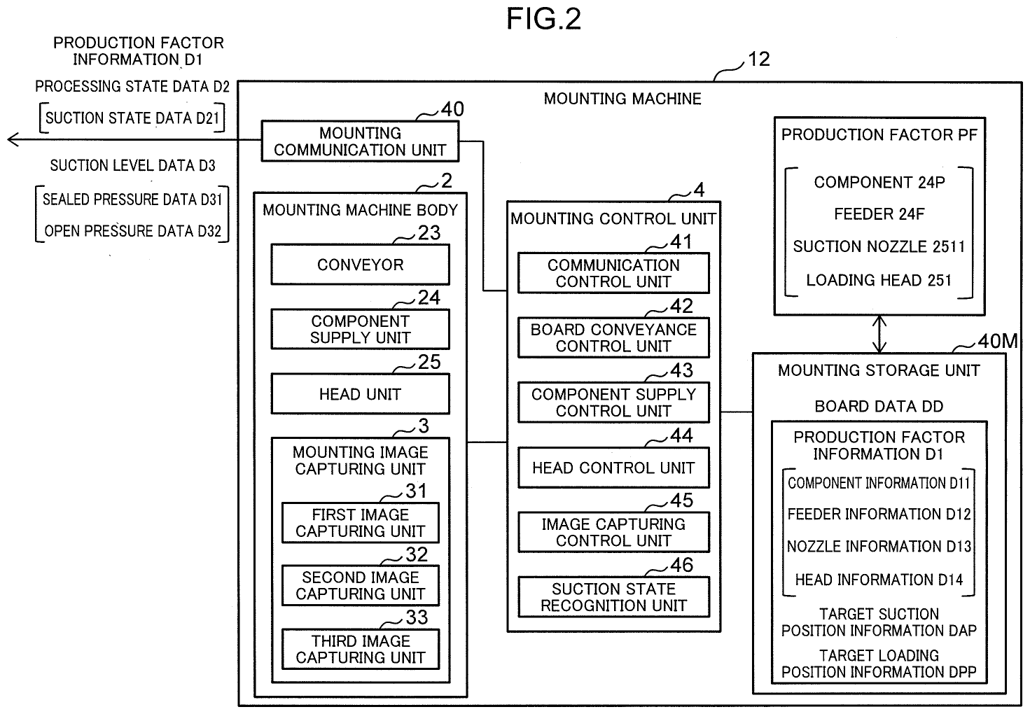

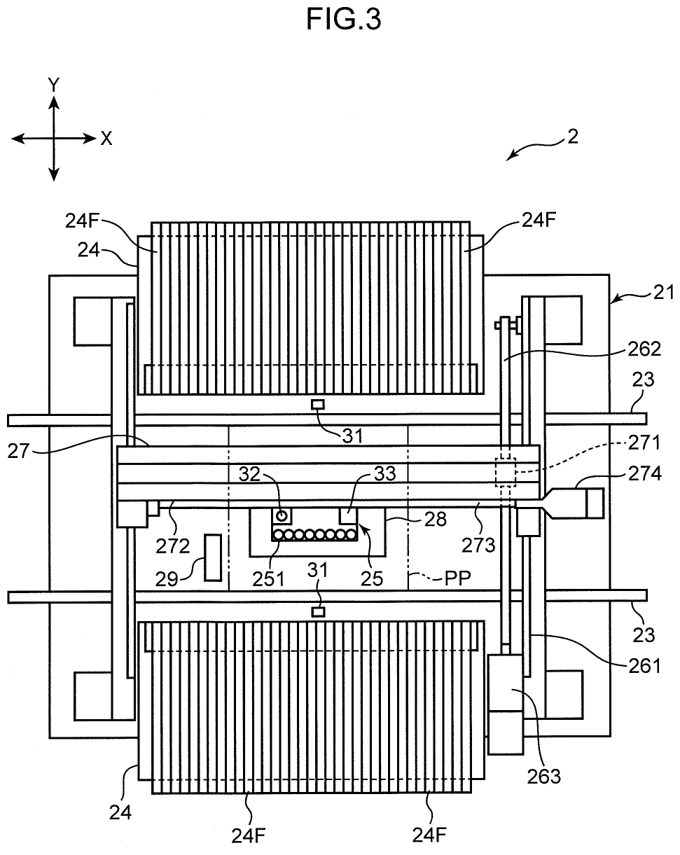

The mounting machine 12 will be described with reference to FIGS. 2 to 4 in addition to FIG. 1. Note that FIG. 3 shows the orientation relationship using XY orthogonal coordinates that are orthogonal to each other on the horizontal plane. The mounting machine 12 is an apparatus for producing the component loading board PPA with electronic components (hereinafter referred to as “component”) loaded on a board PP on which a solder paste is printed.

The mounting machine 12 includes a mounting machine body 2, a mounting control unit 4, a mounting communication unit 40, and a mounting storage unit 40M. The mounting machine body 2 constitutes a structural part that executes a component loading process for loading the component on the board PP, and the like during production of the component loading board PPA. The mounting communication unit 40 is an interface for executing data communication with the management device 14, and has a function of outputting various data and information to the management device 14. The mounting control unit 4 controls the component loading process of the mounting machine body 2 and the like according to board data DD stored in the mounting storage unit 40M and controls the data communication of the mounting communication unit 40.

The mounting machine body 2 includes a body frame 21, a conveyor 23, component supply units 24, a head unit 25, a board support unit 28, and a nozzle station 29.

The body frame 21 is a structure on which respective parts that constitute the mounting machine body 2 are disposed, and is formed in a substantially rectangular shape in plan view when viewed from a direction orthogonal to both the X-axis direction and the Y-axis direction (perpendicular direction). The conveyor 23 extends in the X-axis direction and is disposed on the body frame 21. The conveyor 23 conveys the board PP in the X-axis direction. Positioning of the board PP conveyed on the conveyor 23 is determined by the board support unit 28 at a predetermined work position (component loading position where the component is loaded on the board PP). The board support unit 28 determines positioning of the board PP on the conveyor 23 by supporting the PP from below. Note that FIG. 3 illustrates a single-lane type board conveyance mechanism having one conveyor 23 serving as a lane for conveying the board PP, but this may be a dual-lane type board conveyance mechanism having two conveyors 23.

The component supply units 24 are disposed in regions at both ends of the body frame 21 in the Y-axis direction, with the conveyor 23 interposed therebetween. Each of the component supply units 24 is a region installed in the body frame 21 with a plurality of feeders 24F installed in parallel, and the set position of each feeder 24F is divided for each component 24P to be held by loading heads 251 provided in the head unit 25 to be described later. Each of the feeders 24F is detachably installed in the component supply unit 24. The feeder 24F is a device that executes a component supply process to supply the component. The feeder 24F is not particularly limited as long as the feeder can hold a plurality of components 24P and supply the held components 24P to predetermined component supply positions set in the feeder, and is, for example, a tape feeder. The tape feeder is a feeder including a reel on which a component storage tape that stores the component 24P at predetermined intervals is wound, and configured to supply the component 24P by feeding the component storage tape from the reel.

The head unit 25 is held by a moving frame 27. A fixed rail 261 extending in the Y-axis direction and a ball screw shaft 262 rotationally driven by a Y-axis servomotor 263 are disposed on the body frame 21. The moving frame 27 is disposed on the fixed rail 261, and a nut portion 271 provided in the moving frame 27 is screwed into the ball screw shaft 262. A guide member 272 extending in the X-axis direction and a ball screw shaft 273 driven by an X-axis servomotor 274 are disposed on the moving frame 27. The head unit 25 is movably held by the guide member 272, and the nut portion provided in the head unit 25 is screwed into the ball screw shaft 273. The moving frame 27 is moved by the operation of the Y-axis servomotor 263 in the Y-axis direction, and the head unit 25 is moved by the operation of the X-axis servomotor 274 in the X-axis direction with respect to the moving frame 27. That is, the head unit 25 is movable in the Y-axis direction as the moving frame 27 moves, and is movable in the X-axis direction along the moving frame 27. The head unit 25 is movable between the component supply unit 24 and the board PP supported by the board support unit 28. The head unit 25 executes the component loading process for loading the component 24P onto the board PP by moving between the component supply unit 24 and the board PP.

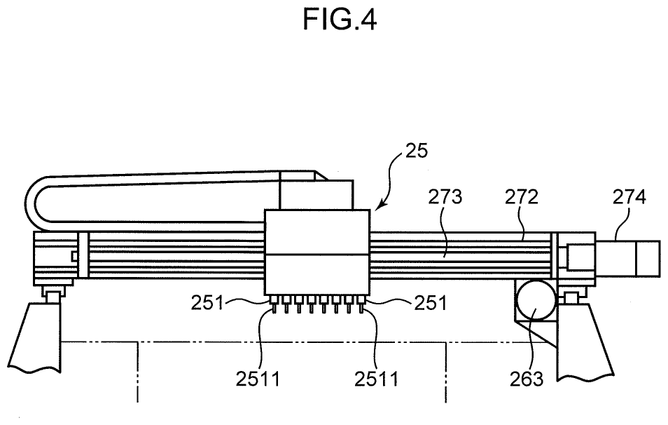

As shown in FIG. 4, the head unit 25 includes the plurality of loading heads 251. Each loading head 251 includes a suction nozzle 2511 installed on the tip (lower end). The suction nozzle 2511 is one example of a holding member that holds the component 24P supplied by the feeder 24F. Examples of the holding member other than the suction nozzle include a gripping member that holds the component 24P by gripping the component 24P. The suction nozzle 2511 is a nozzle capable of suctioning and holding the component 24P supplied by the feeder 24F. The suction nozzle 2511 executes a component suction process for suctioning the component 24P. The suction nozzle 2511 can communicate with any one of a negative pressure generation device, a positive pressure generation device, and the atmosphere via an electric switching valve. That is, the supply of negative pressure to the suction nozzle 2511 enables the suctioning and holding of the component 24P by the suction nozzle 2511. After that, the supply of positive pressure releases the suctioning and holding of the component 24P. Each loading head 251 executes the component loading process for loading the component 24P suctioned and held by the suction nozzle 2511 onto the board PP at each of a plurality of target loading positions set on the board PP. Each loading head 251 obtains the component loading board PPA by executing the component loading process on the PP.

Each loading head 251 can ascend and descend in the Z-axis direction (perpendicular direction) with respect to the frame of the head unit 25, and can rotate around the head axis extending in the Z-axis direction. Each loading head 251 can ascend and descend along the Z-axis direction between a suctionable position where the suction nozzle 2511 can suction and hold the component 24P and a retracted position above the suctionable position. That is, when the suction nozzle 2511 suctions and holds the component 24P, each loading head 251 descends from the retracted position toward the suctionable position, and suctions and holds the component 24P at the suctionable position. Meanwhile, each loading head 251 after suctioning and holding the component 24P ascends from the suctionable position toward the retracted position. Furthermore, each loading head 251 can ascend and descend along the Z-axis direction between a loadable position where the component 24P suctioned and held by the suction nozzle 2511 can be loaded at the predetermined target loading position on the board PP, and the retracted position.

The nozzle station 29 is disposed on the body frame 21 and serves as an accommodation place for accommodating the plurality of suction nozzles 2511. Note that a plurality of the nozzle stations 29 may be disposed on the body frame 21. The suction nozzle 2511 is taken out from the nozzle station 29 and installed in each loading head 251.

As shown in FIGS. 2 and 3, the mounting machine body 2 further includes a mounting image capturing unit 3. The mounting image capturing unit 3 acquires a captured image by executing an image capturing operation of capturing an image of an object to be captured. The mounting image capturing unit 3 includes a first image capturing unit 31, a second image capturing unit 32, and a third image capturing unit 33.

The first image capturing unit 31 is, for example, an image capturing camera installed between the component supply unit 24 and the conveyor 23 on the body frame 21 and including an image capturing element such as a complementary metal-oxide-semiconductor (CMOS) and a charged-coupled device (CCD). When each loading head 251 is executing the component loading process, while the head unit 25 is moving from the component supply unit 24 to the board PP supported by the board support unit 28, the first image capturing unit 31 captures an image of the component 24P suctioned and held by the suction nozzle 2511 of each loading head 251 from below to acquire a suction processing image. The suction processing image is an image indicating a processing state of the component suction process by the suction nozzle 2511. The suction processing image is, for example, an image that allows checking the posture of the component 24P suctioned to the suction nozzle 2511, an offset amount of the suction position of the component 24P from the suction nozzle 2511, and the like as the processing state of the component suction process. The suction processing image is input into the mounting control unit 4 described later, and is referred to when a suction state recognition unit 46 executes a recognition process of the suction state of the component 24P with respect to the suction nozzle 2511.

The second image capturing unit 32 is, for example, an image capturing camera disposed in the head unit 25 and including a CMOS or CCD image capturing element or the like. The second image capturing unit 32 captures an image of the component supply position of the feeder 24F from diagonally above, with the head unit 25 disposed such that the suction nozzle 2511 is positioned directly above the component supply position set in the feeder 24F. Specifically, before the suction nozzle 2511 executes the suction operation, the second image capturing unit 32 acquires a first supply processing image by capturing an image of the component 24P supplied to the component supply position by the feeder 24F from diagonally above. Furthermore, the second image capturing unit 32 captures the state of the component supply position while the suction nozzle 2511 is executing the suction operation on the component 24P supplied to the component supply position by the feeder 24F to acquire a second supply processing image. The second image capturing unit 32 captures the state of the component supply position after the suction nozzle 2511 finishes the suction operation to acquire a third supply processing image. The first supply processing image is an image that allows checking of the posture of the component 24P supplied to the component supply position of the feeder 24F. The second supply processing image and the third supply processing image are images that allow checking of the posture of the component 24P supplied to the component supply position when suctioned by the suction nozzle 2511. The first to third supply processing images are input into the mounting control unit 4, and are referred to when the suction state recognition unit 46 executes the recognition process of the suction state of the component 24P with respect to the suction nozzle 2511.

The second image capturing unit 32 captures an image of the target loading position from diagonally above with the head unit 25 disposed such that the suction nozzle 2511 that suctions and holds the component is positioned directly above the target loading position set on the board PP. Specifically, before the loading head 251 loads the component 24P suctioned by the suction nozzle 2511 onto the board PP, the second image capturing unit 32 captures an image of the target loading position on the board PP from diagonally above to acquire a component pre-loading image. Furthermore, the second image capturing unit 32 captures an image of the state of the target loading position after the loading head 251 finishes the component loading operation to acquire a component post-loading image. The component pre-loading image and the component post-loading image are images showing the processing state of the component loading process by the loading head 251. The component pre-loading image and the component post-loading image are, for example, images that enable checking of the posture of the component 24P loaded at the target loading position on the board PP and the like as the processing state of the component loading process.

The third image capturing unit 33 is, for example, an image capturing camera disposed in the head unit 25 and including a CMOS or CCD image capturing element or the like. To recognize various marks affixed to an upper surface of the board PP supported by the board support unit 28 before each loading head 251 executes the component loading process, the third image capturing unit 33 captures an image of the marks from above. By recognizing the marks on the board PP by the third image capturing unit 33, the position offset amount with respect to origin coordinates of the board PP is detected.

The mounting storage unit 40M stores the board data DD to be referred to by the mounting control unit 4. The board data DD is data including a plurality of pieces of production factor information D1 required to control the component loading process of the mounting machine body 2 and the like by the mounting control unit 4, target suction position information DAP, and target loading position information DPP.

The production factor information D1 is information for identifying production factors PF indicated by any one of the component 24P, the feeder 24F, the suction nozzle 2511, and the loading head 251 used in production of the component loading board PPA in the mounting machine 12. In the present embodiment, the production factor information D1 includes component information D11, feeder information D12, nozzle information D13, and head information D14.

The component information D11 is information for identifying the component 24P out of the production factors PF. In the component information D11, as information for identifying the component 24P, information such as the component name unique to the component 24P, the component type indicating the type of the component 24P, and external dimensions of the component 24P is registered. The feeder information D12 is information for identifying the feeder 24F out of the production factors PF. In the feeder information D12, as information for identifying the feeder 24F, information such as the type of the feeder 24F and the set position of the feeder 24F in the component supply unit 24 is registered. The nozzle information D13 is information for identifying the suction nozzle 2511 out of the production factors PF. In the nozzle information D13, as information for identifying the suction nozzle 2511, information such as the type of the suction nozzle 2511 and an identifier of the suction nozzle 2511 is registered. The head information D14 is information for identifying the loading head 251 out of the production factors PF. In the head information D14, as information for identifying the loading head 251, information such as the serial number of the loading head 251 is registered.

The target suction position information DAP is information in which the target suction position when the suction nozzle 2511 suctions the component 24P (target suction position) is registered. In the target suction position information DAP, coordinates of the target suction position of the component 24P with respect to the suction nozzle 2511 in the X-axis and Y-axis directions are registered. The target suction position is usually set at the central position on the surface to be suctioned in the component 24P. The target loading position information DPP is information in which the target loading position of the component 24P set on the board PP is registered. In the target loading position information DPP, coordinates of the target loading position on the board PP in the X-axis and Y-axis directions are registered.

The mounting control unit 4 includes a central processing unit (CPU), a read only memory (ROM) that stores a control program, a random access memory (RAM) used as a work area for the CPU, and the like. By the CPU executing the control program stored in the ROM, the mounting control unit 4 controls the operation of each constituent element of the mounting machine body 2, controls the data communication operation of the mounting communication unit 40, and further executes various kinds of arithmetic processing. The mounting control unit 4 controls the operation of each constituent element of the mounting machine body 2 according to the board data DD stored in the mounting storage unit 40M. As shown in FIG. 2, the mounting control unit 4 includes, as main functional configurations, a communication control unit 41, a board conveyance control unit 42, a component supply control unit 43, a head control unit 44, an image capturing control unit 45, and the suction state recognition unit 46.

The communication control unit 41 controls data communication between the mounting machine 12 and the management device 14 by controlling the mounting communication unit 40. The mounting communication unit 40 controlled by the communication control unit 41 sends, to the management device 14, suction state data D21 and suction level data D3 (holding level data) output by the suction state recognition unit 46 described later and the production factor information D1 included in the board data DD stored in the mounting storage unit 40M. Note that the production factor information D1 sent to the management device 14 via the mounting communication unit 40 includes the component information D11, the feeder information D12, the nozzle information D13, and the head information D14.

Details will be described later, but the suction state data D21 is data that constitutes processing state data D2, and is data indicating whether the suction state of the component 24P by the suction nozzle 2511 is normal or abnormal. The suction level data D3 is data indicating the suction level of the component 24P by the suction nozzle 2511. The suction level data D3 includes sealed pressure data D31 indicating the negative pressure level when the component 24P is suctioned by the suction nozzle 2511 and open pressure data D32 indicating the negative pressure level when the suction of the component 24P by the suction nozzle 2511 is released. The suction state data D21 and the suction level data D3 are data output from the suction state recognition unit 46.

In one execution of the component suction process by the suction nozzle 2511, one component 24P is used from among the plurality of components 24P, one feeder 24F is used from among the plurality of feeders 24F, one suction nozzle 2511 is used from among the plurality of suction nozzles 2511, and one loading head 251 is used from among the plurality of loading heads 251. That is, for each component suction process by the suction nozzle 2511, the component 24P, the feeder 24F, the suction nozzle 2511, and the loading head 251 that constitute the production factors PF used for production of the component loading board PPA are uniquely determined. Therefore, the production factor information D1 for identifying the production factors PF, and the suction state data D21 and the suction level data D3 output from the suction state recognition unit 46 are information associated with each other for each component suction process by the suction nozzle 2511.

The board conveyance control unit 42 controls the conveyance operation of the board PP by the conveyor 23. The component supply control unit 43 controls the component supply process of each of the plurality of feeders 24F arranged in the component supply unit 24 according to the component information D11 and the feeder information D12 in the board data DD. The head control unit 44 controls the suction nozzle 2511 and the loading head 251 by controlling the head unit 25 according to the component information D11, the nozzle information D13, the head information D14, the target suction position information DAP, and the target loading position information DPP in the board data DD. Accordingly, the head control unit 44 executes the component suction process by the suction nozzle 2511 and executes the component loading process by the loading head 251 corresponding to each of the plurality of target loading positions set on the board PP. The image capturing control unit 45 controls the image capturing operation by the first image capturing unit 31, the second image capturing unit 32, and the third image capturing unit 33 that constitute the mounting image capturing unit 3.

The suction state recognition unit 46 recognizes the suction state of the component 24P by the suction nozzle 2511 based on the suction processing image acquired by the first image capturing unit 31 and the first to third supply processing images acquired by the second image capturing unit 32. Then, the suction state recognition unit 46 outputs the suction state data D21 indicating whether the suction state of the component 24P by the suction nozzle 2511 is normal or abnormal.

Specifically, the suction state recognition unit 46 recognizes whether the component 24P is suctioned to the suction nozzle 2511 based on the suction processing image. When the component 24P is not suctioned to the suction nozzle 2511, the suction state recognition unit 46 recognizes that a suction error of component fall indicating the fall of the component 24P from the suction nozzle 2511 has occurred, and outputs the suction state data D21 to which information on the component fall error is added. Meanwhile, when the component 24P is suctioned to the suction nozzle 2511, the suction state recognition unit 46 recognizes the actual suction position indicating the actual suction position of the component 24P by the suction nozzle 2511 based on the suction processing image. When the actual suction position deviates from the target suction position indicated by the target suction position information DAP by more than the allowable range, the suction state recognition unit 46 recognizes that a suction error of suction position offset has occurred and outputs the suction state data D21 to which information on the suction position offset error is added.

The suction state recognition unit 46 recognizes the posture of the component 24P that is suctioned and held by the suction nozzle 2511 based on the first to third supply processing images. When the component 24P suctioned and held by the suction nozzle 2511 is in an abnormal posture, the suction state recognition unit 46 recognizes that a suction error of component posture has occurred, and outputs the suction state data D21 to which information on the component posture error is added.

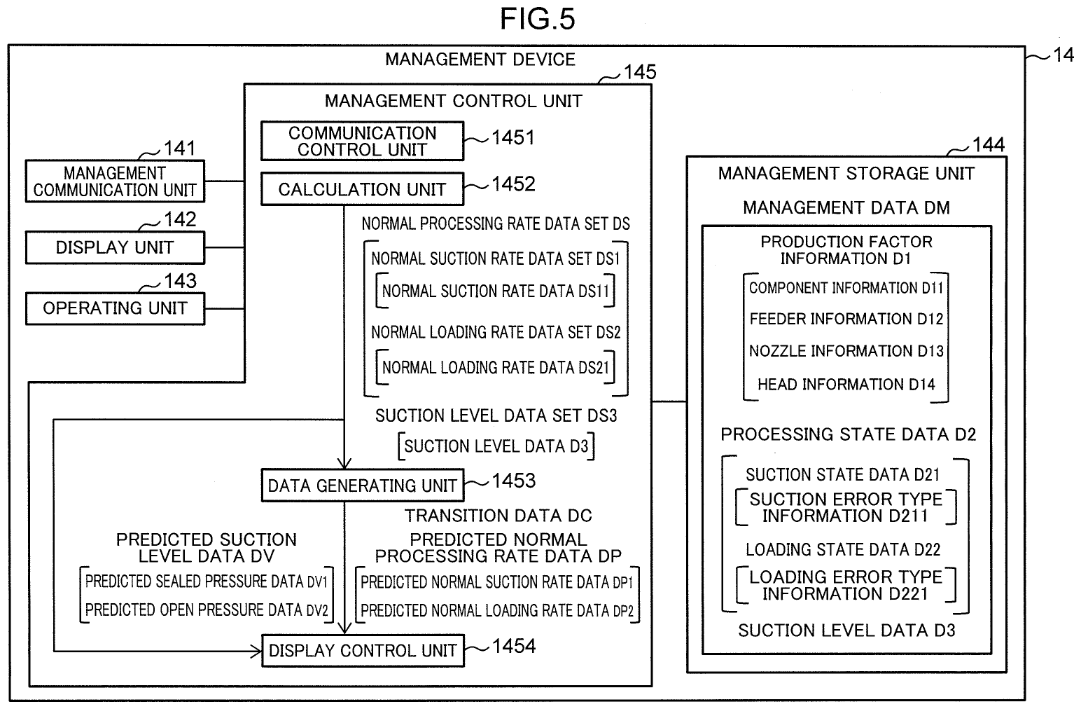

As described above, when the suction error occurs in the component suction process by the suction nozzle 2511, the suction state recognition unit 46 outputs the suction state data D21 to which suction error type information D211 (FIG. 5 describe later) indicating the type of suction error such as the component fall error, suction position offset error, and component posture error is added. The suction state data D21 output from the suction state recognition unit 46 is sent to the management device 14 via the mounting communication unit 40 in association with the component information D11, the feeder information D12, the nozzle information D13, and the head information D14 that constitute the production factor information D1.

The suction state recognition unit 46 acquires data on the negative pressure level of the negative pressure generation device connected to the suction nozzle 2511 as the suction level data D3 indicating the suction level of the component by the suction nozzle 2511 in the component suction process. The suction level data D3 includes sealed pressure data D31 indicating the negative pressure level when the component 24P is suctioned by the suction nozzle 2511 and open pressure data D32 indicating the negative pressure level when the suction of the component 24P by the suction nozzle 2511 is released. The suction state recognition unit 46 outputs the acquired suction level data D3. The suction level data D3 output from the suction state recognition unit 46 is sent to the management device 14 via the mounting communication unit 40 in association with the component information D11, the feeder information D12, the nozzle information D13, and the head information D14 that constitute the production factor information D1.

Returning to FIG. 1, the component loading board PPA produced by the mounting machine 12 is brought into the inspection device 13. The inspection device 13 is a device for inspecting the loading state of the component 24P on the component loading board PPA. The inspection device 13 may inspect the component loading board PPA before the reflow process of melting and then hardening solder on the component loading board PPA, and may inspect the component loading board PPA after the reflow process.

The inspection device 13 outputs loading state data D22 indicating whether the loading state of the component 24P on the component loading board PPA is normal or abnormal. The loading state data D22 is data that constitutes the processing state data D2.

Specifically, the inspection device 13 inspects the posture of the component 24P on the component loading board PPA, the offset amount of the loading position of the component 24P, and the like. When the component 24P on the component loading board PPA is in an abnormal posture, the inspection device 13 recognizes that a loading error of component posture has occurred and outputs the loading state data D22 to which information on the component posture error is added. When the offset amount of the loading position of the component 24P from the target loading position indicated by the target loading position information DPP exceeds the allowable range, the inspection device 13 recognizes that a loading error of loading position offset has occurred, and outputs the loading state data D22 to which information on the loading position offset error is added.

The inspection device 13 inspects coplanarity of the component loading board PPA, and a pitch, lead width, the number of leads, and the like of leads of the component 24P on the component loading board PPA. Coplanarity of the component loading board PPA refers to flatness of the component loading board PPA by using the maximum gap between contact points such as the lead and solder ball of the component 24P and the board surface as an indicator. When the maximum gap exceeds the allowable range, the inspection device 13 recognizes that a loading error of coplanarity on the component loading board PPA has occurred, and outputs the loading state data D22 to which information on the coplanarity error is added. When the lead pitch of the component 24P on the component loading board PPA exceeds the allowable range, the inspection device 13 recognizes that a loading error of the lead pitch of the component 24P has occurred, and outputs the loading state data D22 to which information on the lead pitch error is added. When the lead width of the component 24P on the component loading board PPA exceeds the allowable range, the inspection device 13 recognizes that a loading error of the lead width of the component 24P has occurred, and outputs the loading state data D22 to which information on the lead width error is added. When the number of leads of the component 24P on the component loading board PPA indicates an abnormal value, the inspection device 13 recognizes that a loading error of the number of leads of the component 24P has occurred, and outputs the loading state data D22 to which information on the number of leads error is added.

As described above, when the loading error indicating an abnormality in the loading state of the component 24P on the component loading board PPA has occurred, the inspection device 13 outputs the loading state data D22 to which loading error type information D221 indicating the type of loading error (FIG. 5 described later) is added, such as a component posture error, loading position offset error, coplanarity error, lead pitch error, lead width error, and the number of leads error. The loading state data D22 output from the inspection device 13 is sent to the management device 14.

The management device 14 is a device for managing the production of the component loading board PPA in the mounting machines 12. The management device 14 is connected to the mounting machine 12 and the inspection device 13 in a way that allows data communication, and includes, for example, a microcomputer. The production factor information D1 from the mounting machine 12, the suction state data D21 that constitutes the processing state data D2, and the suction level data D3 are input into the management device 14, and the loading state data D22 that constitutes the processing state data D2 from the inspection device 13 is input. The management device 14 is operated by the operator.

The management device 14 will be described with reference to the block diagram of FIG. 5 and FIGS. 6 to 9. The management device 14 includes a management communication unit 141, a display unit 142, an operating unit 143, a management storage unit 144, and a management control unit 145.

The management communication unit 141 is an interface for executing data communication with the mounting machine 12 and the inspection device 13. The management communication unit 141 acquires the production factor information D1, the suction state data D21, and the suction level data D3 from the mounting machine 12, and acquires the loading state data D22 from the inspection device 13.

The management storage unit 144 accumulates and stores various pieces of information and data acquired by the management communication unit 141. The management storage unit 144 accumulates and stores management data DM in which the production factor information D1, the processing state data D2 including the suction state data D21 and the loading state data D22, and the suction level data D3 are associated with one another for each use of the production factors PF indicated by the production factor information D1. Note that as described above, the suction error type information D211 is added to the suction state data D21 stored in the management storage unit 144, and the loading error type information D221 is added to the loading state data D22.

The display unit 142 is configured to display various data. The display unit 142 includes, for example, a liquid crystal display or the like. The operating unit 143 includes a keyboard, a mouse, a touch panel provided in the display unit 142, or the like. The operating unit 143 receives various command input operations by the operator about a display mode of the display unit 142.

The management control unit 145 includes, as main functional configurations, a communication control unit 1451, a calculation unit 1452, a data generating unit 1453, and a display control unit 1454.

The communication control unit 1451 controls data communication between the management device 14 and the mounting machine 12, and controls data communication between the management device 14 and the inspection device 13 by controlling the management communication unit 141.

The calculation unit 1452 calculates normal processing rate data including normal suction rate data DS11 and normal loading rate data DS21 based on a data group of the management data DM accumulated and stored in the management storage unit 144 within an actual production period PR1 from prescribed time point TS to current time point TP. The actual production period PR1 indicates the period in which the production factors PF are used in the mounting machine 12 to produce the component loading board PPA. The prescribed time point TS representing the starting point of the actual production period PR1 indicates, for example, the time when maintenance is executed for the feeder 24F, the suction nozzle 2511, and the loading head 251 out of the production factors PF. The current time point TP representing the end point of the actual production period PR1 indicates, for example, the current time point when production of the component loading board PPA of the same lot ends.

The calculation unit 1452 calculates the normal suction rate data DS11 and the normal loading rate data DS21 for each use time point TU when the production factors PF are used within the actual production period PR1. The normal suction rate data DS11 is, regarding the number of uses of the production factors PF between the prescribed time point TS and the use time point TU, data indicating the ratio of the number of uses when the suction state of the component 24P by the suction nozzle 2511 is normal to the total number of uses of the production factors PF. The normal loading rate data DS21 is, regarding the number of uses of the production factors PF between the prescribed time point TS and the use time point TU, data indicating the ratio of the number of uses when the loading state of the component 24P on the component loading board PPA is normal to the total number of uses of the production factors PF.

The calculation unit 1452 outputs a normal processing rate data set DS in association with each piece of the production factor information D1 based on the normal suction rate data DS11 and the normal loading rate data DS21 for each use time point TU calculated as described above. Specifically, the calculation unit 1452 outputs the normal processing rate data set DS in association with each of the component information D11, the feeder information D12, the nozzle information D13, and the head information D14 that constitute the production factor information D1. The normal processing rate data set DS includes a normal suction rate data set DS1 and a normal loading rate data set DS2. The normal suction rate data set DS1 is a data set that includes, as one set, the data group of the normal suction rate data DS11 for each use time point TU within the actual production period PR1. The normal loading rate data set DS2 is a data set that includes, as one set, the data group of the normal loading rate data DS21 for each use time point TU within the actual production period PR1. The calculation unit 1452 outputs the normal suction rate data set DS1 in association with each piece of the production factor information D1, and outputs the normal loading rate data set DS2 in association with each piece of the production factor information D1.

When the management data DM accumulated and stored in the management storage unit 144 includes the suction level data D3, the calculation unit 1452 outputs a suction level data set DS3 (holding level data set) in association with each piece of the production factor information D1. The suction level data set DS3 is a data set that includes, as one set, the data group of the suction level data D3 for each use time point TU within the actual production period PR1.

Regarding the processing state data D2 included in the management data DM accumulated and stored in the management storage unit 144, it is assumed that the suction error type information D211 is added to the suction state data D21, and the loading error type information D221 is added to the loading state data D22. In this case, the calculation unit 1452 outputs the normal suction rate data set DS1 indicated by the data group of the normal suction rate data DS11 to which the suction error type information D211 is added, in association with each piece of the production factor information D1. Furthermore, the calculation unit 1452 outputs the normal loading rate data set DS2 indicated by the data group of the normal loading rate data DS21 to which the loading error type information D221 is added, in association with each piece of the production factor information D1.

The data generating unit 1453 generates predicted normal processing rate data DP in association with each piece of the production factor information based on the normal processing rate data set DS output from the calculation unit 1452. Specifically, the data generating unit 1453 generates the predicted normal processing rate data DP in association with each of the component information D11, the feeder information D12, the nozzle information D13, and the head information D14 that constitute the production factor information D1. The predicted normal processing rate data DP includes predicted normal suction rate data DP1 and predicted normal loading rate data DP2. The predicted normal suction rate data DP1 is data indicating a predicted value of the normal suction rate data DS11 subsequent to the current time point TP according to the change in a use variable UV indicated by at least one of the number of uses UV1 and the use time UV2 of each production factor PF. The predicted normal loading rate data DP2 is data indicating a predicted value of the normal loading rate data DS21 subsequent to the current time point TP according to the change in the use variable UV of each production factor PF.

The data generating unit 1453 generates transition data DC based on the normal processing rate data set DS, and generates the predicted normal processing rate data DP based on the transition data DC.

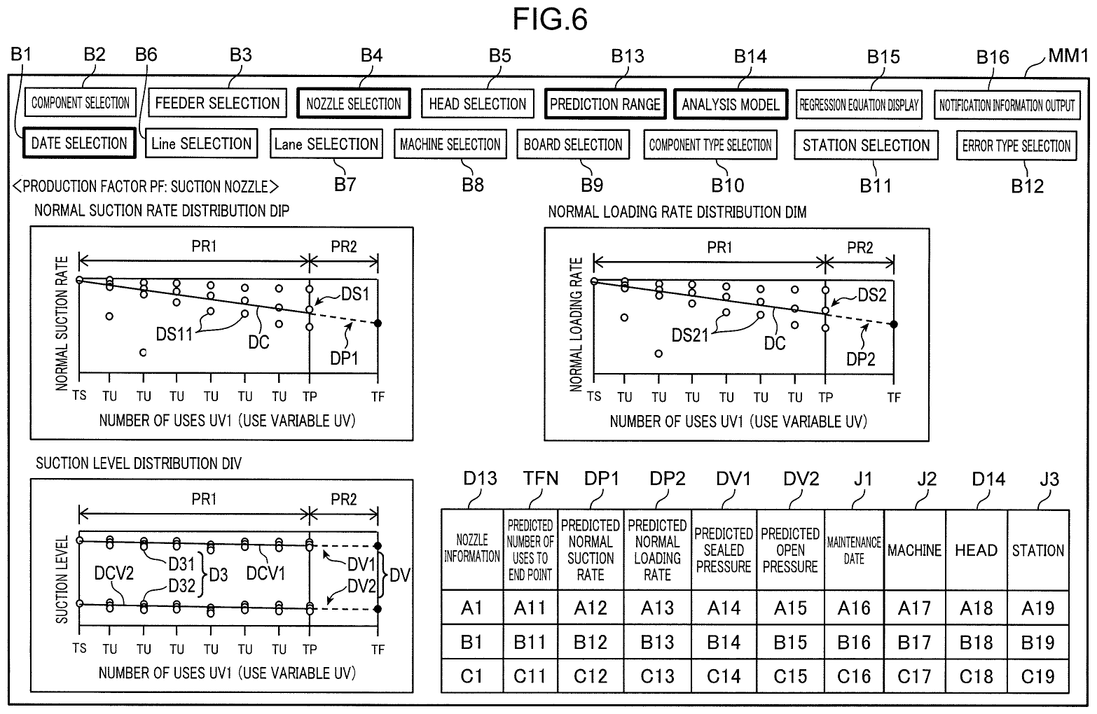

Specifically, the data generating unit 1453 generates the transition data DC based on the normal suction rate data set DS1 that constitutes the normal processing rate data set DS. In this case, the transition data DC is data indicating the transition of the normal suction rate data DS11 according to the change in the use variable UV within the actual production period PR1 (see FIGS. 6 to 9 and the like). Then, the data generating unit 1453 generates the predicted normal suction rate data DP1 that constitutes the predicted normal processing rate data DP by extending the transition data DC to the current time point TP and beyond regarding the use variable UV. The data generating unit 1453 generates the transition data DC based on the normal loading rate data set DS2 that constitutes the normal processing rate data set DS. In this case, the transition data DC is data indicating the transition of the normal loading rate data DS21 according to the change in the use variable UV within the actual production period PR1. Then, the data generating unit 1453 generates the predicted normal loading rate data DP2 that constitutes the predicted normal processing rate data DP by extending the transition data DC to the current time point TP and beyond regarding the use variable UV.

In the present embodiment, the data generating unit 1453 determines a regression equation through regression analysis with the use variable UV as an explanatory variable and the normal suction rate data DS11 and the normal loading rate data DS21 as dependent variables, and generates a regression line based on the regression equation as the transition data DC. Then, by extending the transition data DC (regression line) to the current time point TP and beyond regarding the use variable UV (explanatory variable), the data generating unit 1453 generates the predicted normal suction rate data DP1 and the predicted normal loading rate data DP2.

The regression equation can be expressed as an approximate equation that approximates the correlation between the normal suction rate data DS11 and the normal loading rate data DS21, and the use variable UV. Examples of the approximate equation include linear approximation, polynomial approximation, logarithmic approximation, exponential approximation, and power approximation.

In a case where the dependent variables indicated by the normal suction rate data DS11 and the normal loading rate data DS21 increase or decrease at a certain rate when the explanatory variable indicated by the use variable UV changes in the increasing direction, a linear approximation equation is preferably selected as the regression equation. In a case where the dependent variables alternate between increasing and decreasing when the explanatory variable changes in the increasing direction, a polynomial approximation equation is preferably selected as the regression equation. In a case where the dependent variables change at a decreasing change rate and converge to a predetermined value when the explanatory variable changes in the increasing direction, a power approximation equation that defines a convergence value is preferably selected as the regression equation. In a case where the dependent variables change at a decreasing change rate and do not converge when the explanatory variable changes in the increasing direction, a logarithmic approximation equation or a power approximation equation is preferably selected as the regression equation. In a case where the dependent variables change at an increasing change rate when the explanatory variable changes in the increasing direction, an exponential approximation equation or a power approximation equation is preferably selected as the regression equation.

When the suction level data set DS3 is output from the calculation unit 1452, based on the suction level data set DS3, the data generating unit 1453 generates predicted suction level data DV (predicted holding level data) in association with each piece of the production factor information D1. Specifically, the data generating unit 1453 generates the predicted suction level data DV in association with each of the component information D11, the feeder information D12, the nozzle information D13, and the head information D14 that constitute the production factor information D1. The predicted suction level data DV is data indicating a predicted value of the suction level data D3 subsequent to the current time point TP according to the change in the use variable UV of each production factor PF. The predicted suction level data DV includes predicted sealed pressure data DV1 indicating a predicted value of the sealed pressure data D31 subsequent to the current time point TP and predicted open pressure data DV2 indicating a predicted value of the open pressure data D32 subsequent to the current time point TP.

The data generating unit 1453 generates sealed pressure transition data DCV1 (see FIGS. 6 to 9 and the like) and generates the predicted sealed pressure data DV1 based on the sealed pressure transition data DCV1. The sealed pressure transition data DCV1 is data indicating the transition of the sealed pressure data D31 according to the change in the use variable UV within the actual production period PR1. Then, the data generating unit 1453 generates the predicted sealed pressure data DV1 by extending the sealed pressure transition data DCV1 to the current time point TP and beyond regarding the use variable UV. The data generating unit 1453 generates open pressure transition data DCV2 (see FIGS. 6 to 9 and the like) and generates the predicted open pressure data DV2 based on the open pressure transition data DCV2. The open pressure transition data DCV2 is data indicating the transition of the open pressure data D32 according to the change in the use variable UV within the actual production period PR1. Then, the data generating unit 1453 generates the predicted open pressure data DV2 by extending the open pressure transition data DCV2 to the current time point TP and beyond regarding the use variable UV.

In the present embodiment, the data generating unit 1453 determines a regression equation through regression analysis with the use variable UV as an explanatory variable and the sealed pressure data D31 as a dependent variable, and generates a regression line based on the regression equation as the sealed pressure transition data DCV1. Then, by extending the sealed pressure transition data DCV1 (regression line) to the current time point TP and beyond regarding the use variable UV (explanatory variable), the data generating unit 1453 generates the predicted sealed pressure data DV1. The data generating unit 1453 determines a regression equation through regression analysis with the use variable UV as an explanatory variable and the open pressure data D32 as a dependent variable, and generates a regression line based on the regression equation as the open pressure transition data DCV2. Then, by extending the open pressure transition data DCV2 (regression line) to the current time point TP and beyond regarding the use variable UV (explanatory variable), the data generating unit 1453 generates the predicted open pressure data DV2.

Next, the display control unit 1454 controls the display unit 142 in response to a command input into the operating unit 143. As shown in FIGS. 6 to 9, the display control unit 1454 controls the display unit 142 such that operation regions that enable input operations via the operating unit 143 are set in the display screen.

Examples of the operation regions set in the display screen of the display unit 142 include a date selection region B1, a component selection region B2, a feeder selection region B3, a nozzle selection region B4, a head selection region B5, a Line selection region B6, a Lane selection region B7, a machine selection region B8, a board selection region B9, a component type selection region B10, a station selection region B11, an error type selection region B12, a prediction range setting region B13, an analysis model setting region B14, a regression equation display setting region B15, and a notification information output setting region B16.

The date selection region B1 is a region that allows input of a command to select the actual production period PR1 that is a target period when the calculation unit 1452 calculates the normal suction rate data DS11 and the normal loading rate data DS21.

The component selection region B2, the feeder selection region B3, the nozzle selection region B4, and the head selection region B5 are regions that allow input of a factor selection command to select any one of the component 24P, the feeder 24F, the suction nozzle 2511, and the loading head 251 that constitute the production factors PF.

The Line selection region B6, the Lane selection region B7, the machine selection region B8, the board selection region B9, the component type selection region B10, and the station selection region B11 are regions that allow input of a command to set a narrowing condition for narrowing the plurality of pieces of production factor information D1 set for the production factors PF. The Line selection region B6 allows input of a command to set selection of one mounting line 11 from among the plurality of mounting lines 11 that constitutes the component mounting line 10 as the narrowing condition. When the mounting machine 12 equipped with a dual-lane type board conveyance mechanism including two conveyors 23 is applied to the production of the component loading board PPA, the Lane selection region B7 allows input of a command to set selection of one lane out of the dual lanes as the narrowing condition. The machine selection region B8 allows input of a command to set selection of one mounting machine 12 from among the plurality of mounting machines 12 on the component mounting line 10 as the narrowing condition. The board selection region B9 allows input of a command to set selection of one board PP from among the plurality of boards PP used in the production of the component loading board PPA by the mounting machine 12 as the narrowing condition. The component type selection region B10 allows input of a command to set selection of one component type from among the plurality of component types of the component 24P used in the production of the component loading board PPA by the mounting machine 12 as the narrowing condition. When the plurality of nozzle stations 29 accommodating the plurality of suction nozzles 2511 is provided in the mounting machine 12, the station selection region B11 allows input of a command to set selection of one of the nozzle stations 29 as the narrowing condition.

The error type selection region B12 is a region that allows input of an error type selection command to select an error type indicated by the suction error type information D211 added to the suction state data D21 or the loading error type information D221 added to the loading state data D22.

The prediction range setting region B13 is a region that allows input of a command to set the range of a prediction period PR2 subsequent to the current time point TP following the actual production period PR1. The prediction range setting region B13 allows input of a command to set the use variable UV used when the data generating unit 1453 generates various data to either the number of uses UV1 or the use time UV2.

The analysis model setting region B14 is a region that allows input of a command to set a method when the data generating unit 1453 determines the regression equation through regression analysis to any one of linear approximation, polynomial approximation, logarithmic approximation, exponential approximation, and power approximation.

The regression equation display setting region B15 is a region that allows input of a command to cause the display unit 142 to display the regression equation determined by the data generating unit 1453.

The notification information output setting region B16 is a region that allows input of a command to cause the data generating unit 1453 to output notification information described later.

It is assumed that the factor selection command to select any one of the component 24P, the feeder 24F, the suction nozzle 2511, and the loading head 251 that constitute the production factors PF, and a use variable setting command to set the use variable UV to either the number of uses UV1 or the use time UV2 are input via the operating unit 143. In this case, the factor selection command is input into the component selection region B2, the feeder selection region B3, the nozzle selection region B4, and the head selection region B5, and the use variable setting command is input into the prediction range setting region B13. In this case, the display control unit 1454 controls the display unit 142 to display data according to the change in the use variable UV indicated by the use variable setting command, the data including the predicted normal suction rate data DP1 and the predicted normal loading rate data DP2 associated with the production factor information D1 corresponding to the production factor PF indicated by the factor selection command.

The display control unit 1454 may control the display unit 142 to display data according to the change in the use variable UV indicated by the use variable setting command simultaneously with the predicted normal suction rate data DP1 and the predicted normal loading rate data DP2, the data including the predicted suction level data DV including the predicted sealed pressure data DV1 and the predicted open pressure data DV2 associated with the production factor information D1 corresponding to the production factor PF indicated by the factor selection command.

FIG. 6 shows an example where the factor selection command to select the suction nozzle 2511 is input into the nozzle selection region B4, and the use variable setting command to set the number of uses UV1 as the use variable UV is input into the prediction range setting region B13. In this case, the display control unit 1454 controls the display unit 142 to display data according to the change in the number of uses UV1 simultaneously on the display screen MM1, the data including the predicted normal suction rate data DP1 and the predicted normal loading rate data DP2, and the predicted suction level data DV associated with the nozzle information D13 corresponding to the suction nozzle 2511.

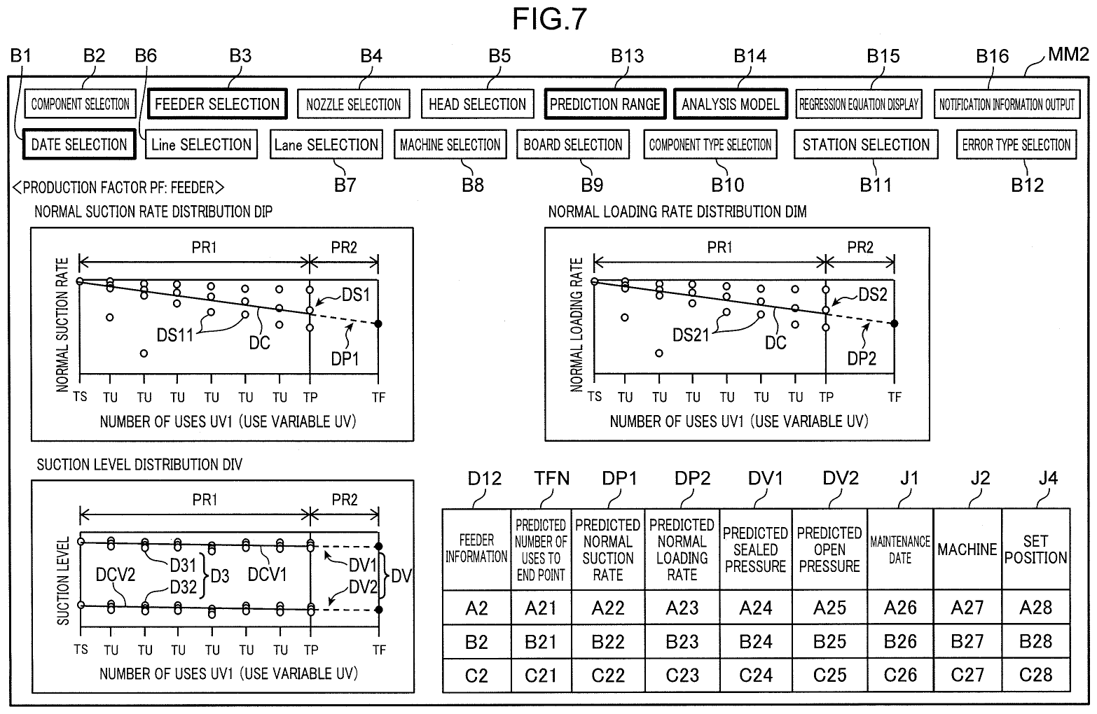

FIG. 7 shows an example where the factor selection command to select the feeder 24F is input into the feeder selection region B3, and the use variable setting command to set the number of uses UV1 as the use variable UV is input into the prediction range setting region B13. In this case, the display control unit 1454 controls the display unit 142 to display data according to the change in the number of uses UV1 simultaneously on the display screen MM2, the data including the predicted normal suction rate data DP1 and the predicted normal loading rate data DP2, and the predicted suction level data DV associated with the feeder information D12 corresponding to the feeder 24F.

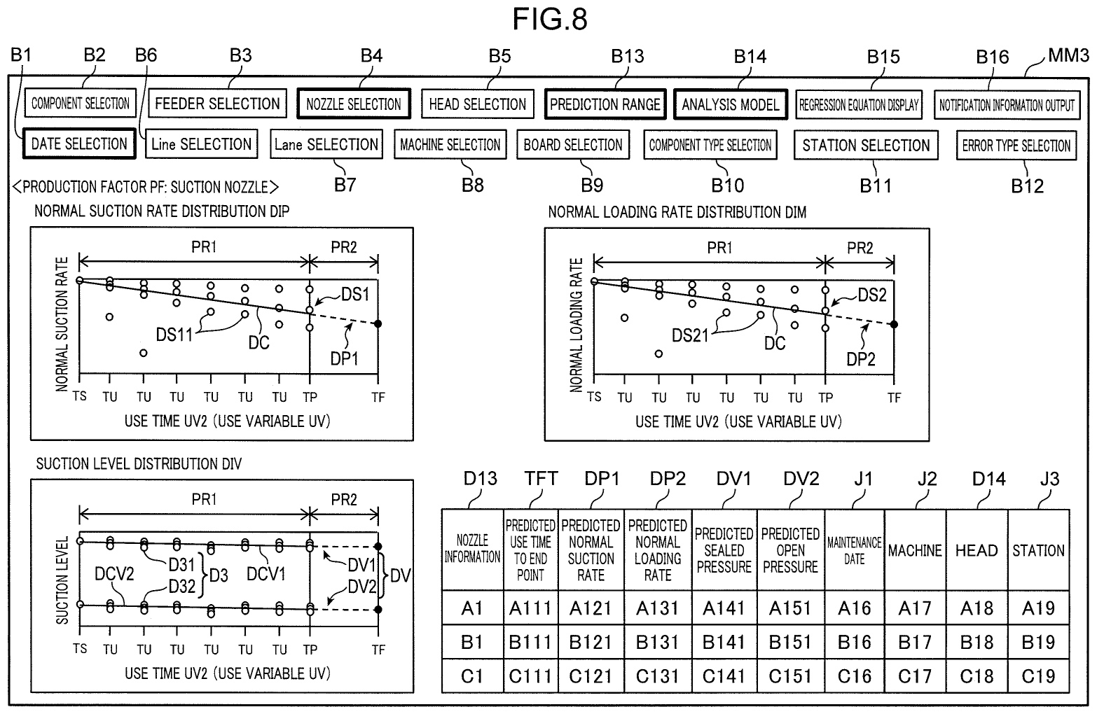

FIG. 8 shows an example where the factor selection command to select the suction nozzle 2511 is input into the nozzle selection region B4, and the use variable setting command to set the use time UV2 as the use variable UV is input into the prediction range setting region B13. In this case, the display control unit 1454 controls the display unit 142 to display data according to the change in the use time UV2 simultaneously on the display screen MM3, the data including the predicted normal suction rate data DP1 and the predicted normal loading rate data DP2, and the predicted suction level data DV associated with the nozzle information D13 corresponding to the suction nozzle 2511.

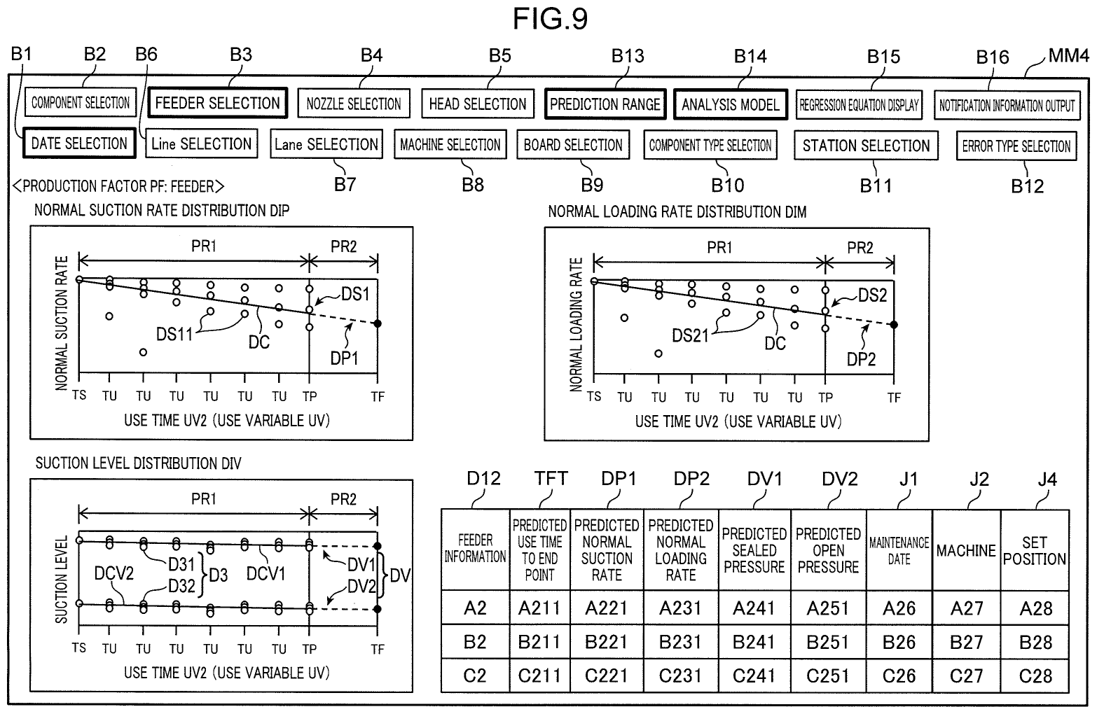

FIG. 9 shows an example where the factor selection command to select the feeder 24F is input into the feeder selection region B3, and the use variable setting command to set the use time UV2 as the use variable UV is input into the prediction range setting region B13. In this case, the display control unit 1454 controls the display unit 142 to display data according to the change in the use time UV2 simultaneously on the display screen MM4, the data including the predicted normal suction rate data DP1 and the predicted normal loading rate data DP2, and the predicted suction level data DV associated with the feeder information D12 corresponding to the feeder 24F.

Based on the predicted normal suction rate data DP1 displayed in the display unit 142, the operator can predict the future suction error (abnormality) generating status according to the use of the production factor PF indicated by the factor selection command subsequent to the current time point TP. Therefore, the operator can predict the frequency and timing of maintenance for the production factor PF in order to suppress the suction error generation in the future subsequent to the current time point TP, and can execute maintenance accurately. Similarly, based on the predicted normal loading rate data DP2 displayed in the display unit 142, the operator can predict the future loading error (abnormality) generating status according to the use of the production factor PF indicated by the factor selection command subsequent to the current time point TP. Therefore, the operator can predict the frequency and timing of maintenance for the production factor PF in order to suppress the loading error generation in the future subsequent to the current time point TP, and can execute maintenance accurately.

Based on the predicted suction level data DV displayed in the display unit 142, the operator can predict the future error (abnormality) generating status caused by the negative pressure generation device connected to the suction nozzle 2511 subsequent to the current time point TP. Therefore, the operator can predict the frequency and timing of maintenance for the negative pressure generation device in order to suppress the error generation in the future subsequent to the current time point TP.

Note that as shown in FIGS. 6 to 9, the display control unit 1454 may control the display unit 142 to display, as tabular information, the predicted normal suction rate data DP1, the predicted normal loading rate data DP2, the predicted sealed pressure data DV1, and the predicted open pressure data DV2.

FIG. 6 shows an example of tabular information displayed in the display unit 142 in which the predicted normal suction rate data DP1, the predicted normal loading rate data DP2, the predicted sealed pressure data DV1, and the predicted open pressure data DV2 are associated with the nozzle information D13, predicted number of uses to end point information TFN, maintenance information J1, machine information J2, the head information D14, and station information J3. In this case, the nozzle information D13 is information that identifies the suction nozzle 2511 selected by the factor selection command. The head information D14 is information that identifies the loading head 251 in which the suction nozzle 2511 is installed. The maintenance information J1 is information indicating the latest maintenance date of the suction nozzle 2511. The machine information J2 is information that identifies the mounting machine 12 where the suction nozzle 2511 is used. The station information J3 is information that identifies the nozzle station 29 where the suction nozzle 2511 is accommodated. The predicted number of uses to end point information TFN is information indicating the predicted number of uses of the suction nozzle 2511 from the prescribed time point TS to the end point TF of the prediction period PR2.

FIG. 7 shows an example of tabular information displayed in the display unit 142 in which the predicted normal suction rate data DP1, the predicted normal loading rate data DP2, the predicted sealed pressure data DV1, and the predicted open pressure data DV2 are associated with the feeder information D12, the predicted number of uses to end point information TFN, the maintenance information J1, the machine information J2, and set position information J4. In this case, the feeder information D12 is information that identifies the feeder 24F selected by the factor selection command. The maintenance information J1 is information indicating the latest maintenance date of the feeder 24F. The machine information J2 is information that identifies the mounting machine 12 where the feeder 24F is used. The set position information J4 is information that identifies the set position of the feeder 24F in the component supply unit 24. The predicted number of uses to end point information TEN is information indicating the predicted number of uses of the feeder 24F from the prescribed time point TS to the end point TF of the prediction period PR2.

FIG. 8 shows an example of tabular information displayed in the display unit 142 in which predicted use time to end point information TFT instead of the predicted number of uses to end point information TFN in FIG. 6 is associated with the predicted normal suction rate data DP1, the predicted normal loading rate data DP2, the predicted sealed pressure data DV1, and the predicted open pressure data DV2. In this case, the predicted use time to end point information TFT is information indicating the predicted use time of the suction nozzle 2511 from the prescribed time point TS to the end point TF of the prediction period PR2.

FIG. 9 shows an example of tabular information displayed in the display unit 142 in which the predicted use time to end point information TFT instead of the predicted number of uses to end point information TFN in FIG. 7 is associated with the predicted normal suction rate data DP1, the predicted normal loading rate data DP2, the predicted sealed pressure data DV1, and the predicted open pressure data DV2. In this case, the predicted use time to end point information TFT is information indicating the predicted use time of the feeder 24F from the prescribed time point TS to the end point TF of the prediction period PR2.

Here, the plurality of pieces of production factor information D1 is set for the production factors PF used in the production of the component loading board PPA in some cases. That is, in the production of the component loading board PPA, when the plurality of feeders 24F and the plurality of suction nozzles 2511 are used, a plurality of pieces of the feeder information D12 is set, and a plurality of pieces of the nozzle information D13 is set. In this case, the calculation unit 1452 outputs the plurality of normal suction rate data sets DS1 and the plurality of normal loading rate data sets DS2 associated with the plurality of pieces of production factor information D1 corresponding to the production factors PF. The calculation unit 1452 outputs the plurality of suction level data sets DS3 associated with the plurality of pieces of production factor information D1 corresponding to the production factors PF.

When the plurality of normal suction rate data sets DS1 is output from the calculation unit 1452 corresponding to the production factors PF, the data generating unit 1453 generates the predicted normal suction rate data DP1 common to the plurality of normal suction rate data sets DS1 corresponding to the production factors PF. Based on such predicted normal suction rate data DP1 that is common to the plurality of normal suction rate data sets DS1 associated with the plurality of pieces of production factor information D1, the operator can predict the future suction error (abnormality) generating status subsequent to the current time point TP with the plurality of feeders 24F and the plurality of suction nozzles 2511 corresponding to the plurality of pieces of production factor information D1 as one group.

Similarly, when the plurality of normal loading rate data sets DS2 is output from the calculation unit 1452 corresponding to the production factors PF, the data generating unit 1453 generates the predicted normal loading rate data DP2 common to the plurality of normal loading rate data sets DS2 corresponding to the production factors PF. Based on such predicted normal loading rate data DP2 that is common to the plurality of normal loading rate data sets DS2 associated with the plurality of pieces of production factor information D1, the operator can predict the future loading error (abnormality) generating status subsequent to the current time point TP with the plurality of feeders 24F and the plurality of suction nozzles 2511 corresponding to the plurality of pieces of production factor information D1 as one group.

When the plurality of suction level data sets DS3 is output from the calculation unit 1452 corresponding to the production factors PF, the data generating unit 1453 generates the predicted suction level data DV common to the plurality of suction level data sets DS3 corresponding to the production factors PF. Based on such predicted suction level data DV common to the plurality of suction level data sets DS3 associated with the plurality of pieces of production factor information D1, the operator can predict the future error (abnormality) generating status caused by the negative pressure generation device connected to the suction nozzle 2511 subsequent to the current time point TP.

As shown in FIGS. 6 to 9, the display control unit 1454 may control the display unit 142 to display normal suction rate distribution DIP simultaneously with the predicted normal suction rate data DP1, and to display normal loading rate distribution DIM simultaneously with the predicted normal loading rate data DP2. The normal suction rate distribution DIP and the normal loading rate distribution DIM are distributions that constitute normal processing rate distribution. The normal suction rate distribution DIP indicates distribution of the data group of the normal suction rate data DS11 indicated by the plurality of normal suction rate data sets DS1 output from the calculation unit 1452. The normal loading rate distribution DIM indicates distribution of the data group of the normal loading rate data DS21 indicated by the plurality of normal loading rate data sets DS2 output from the calculation unit 1452.

As described above, the normal suction rate distribution DIP and the predicted normal suction rate data DP1 are displayed simultaneously in the display unit 142. At this time, the display control unit 1454 may control the display unit 142 such that the transition data DC generated by the data generating unit 1453 is displayed overlapping with the normal suction rate distribution DIP. The operator can predict the future suction error (abnormality) generating status subsequent to the current time point TP based on the predicted normal suction rate data DP1 while checking the distribution of the normal suction rate data DS11 within the actual production period PR1 from the prescribed time point TS to the current time point TP.

Similarly, the normal loading rate distribution DIM and the predicted normal loading rate data DP2 are displayed simultaneously in the display unit 142. At this time, the display control unit 1454 may control the display unit 142 such that the transition data DC generated by the data generating unit 1453 is displayed overlapping with the normal loading rate distribution DIM. The operator can predict the future loading error (abnormality) generating status subsequent to the current time point TP based on the predicted normal loading rate data DP2 while checking the distribution of the normal loading rate data DS21 within the actual production period PR1 from the prescribed time point TS to the current time point TP.

The display control unit 1454 may control the display unit 142 to display suction level distribution DIV simultaneously with the predicted suction level data DV. The suction level distribution DIV indicates distribution of the data group of the suction level data D3 indicated by the plurality of suction level data sets DS3 output from the calculation unit 1452. At this time, the display control unit 1454 may control the display unit 142 such that the sealed pressure transition data DCV1 and the open pressure transition data DCV2 generated by the data generating unit 1453 are displayed overlapping with the suction level distribution DIV. The operator can predict the future error (abnormality) generating status subsequent to the current time point TP caused by the negative pressure generation device connected to the suction nozzle 2511 based on the predicted suction level data DV while checking distribution of the suction level data D3 within the actual production period PR1 from the prescribed time point TS to the current time point TP.

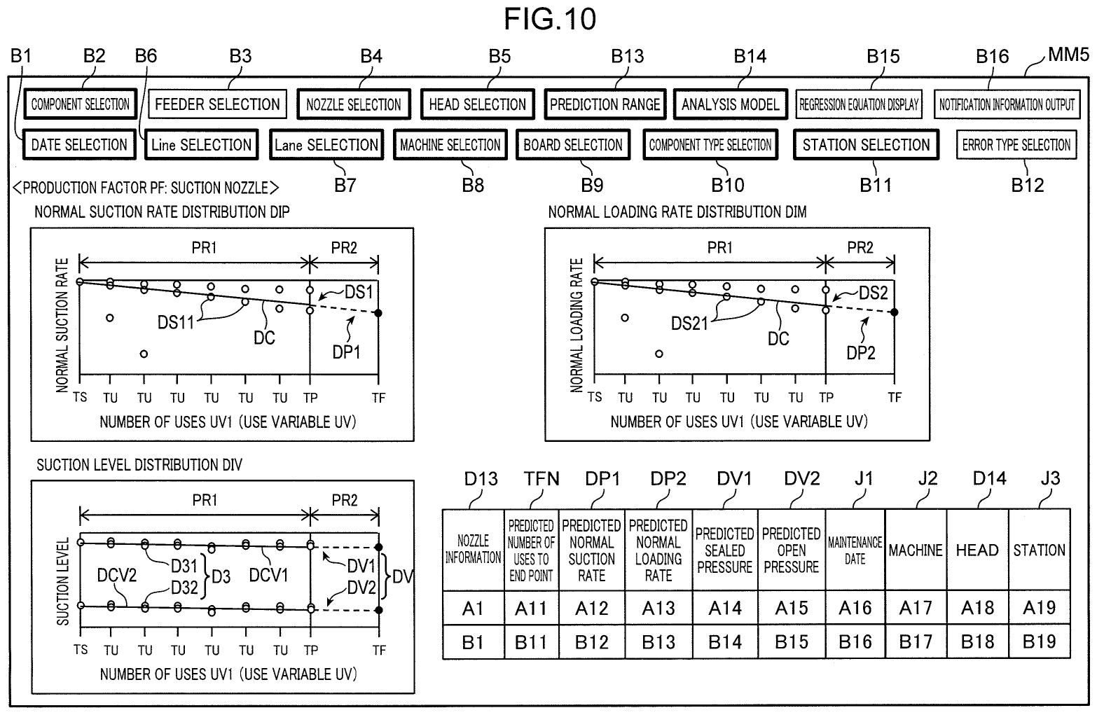

As shown in FIG. 10, the operator can input a command to set the narrowing condition for narrowing down the plurality of pieces of production factor information D1 set for the production factors PF of the feeder 24F and the suction nozzle 2511, by the operation of the component selection region B2, the head selection region B5, the Line selection region B6, the Lane selection region B7, the machine selection region B8, the board selection region B9, the component type selection region B10, and the station selection region B11 set on the display screen MM5 of the display unit 142.

Specifically, when the narrowing condition is set to select the component 24P by the operation of the component selection region B2 using the operating unit 143, the plurality of pieces of production factor information D1 set for the production factors PF is narrowed down to the production factor information D1 related to the component 24P to be selected. When the narrowing condition is set to select the loading head 251 by the operation of the head selection region B5 using the operating unit 143, the plurality of pieces of production factor information D1 set for the production factors PF is narrowed down to the production factor information D1 related to the loading head 251 to be selected. When the narrowing condition to select the mounting line 11 is set by the operation of the Line selection region B6 using the operating unit 143, the plurality of pieces of production factor information D1 set for the production factors PF is narrowed down to the production factor information D1 related to the mounting line 11 to be selected. When the narrowing condition to select one lane among the dual lanes is set by the operation of the Lane selection region B7 using the operating unit 143, the plurality of pieces of production factor information D1 set for the production factors PF is narrowed down to the production factor information D1 related to the lane to be selected. When the narrowing condition to select the mounting machine 12 is set by the operation of the machine selection region B8 using the operating unit 143, the plurality of pieces of production factor information D1 set for the production factors PF is narrowed down to the production factor information D1 related to the mounting machine 12 to be selected. When the narrowing condition to select the board PP is set by the operation of the board selection region B9 using the operating unit 143, the plurality of pieces of production factor information D1 set for the production factors PF is narrowed down to the production factor information D1 related to the board PP to be selected. When the narrowing condition to select the component type of the component 24P is set by the operation of the component type selection region B10 using the operating unit 143, the plurality of pieces of production factor information D1 set for the production factors PF is narrowed down to the production factor information D1 related to the component type to be selected. When the narrowing condition to select the nozzle station 29 is set by the operation of the station selection region B11 using the operating unit 143, the plurality of pieces of production factor information D1 set for the production factors PF is narrowed down to the production factor information D1 related to the nozzle station 29 to be selected.

In this way, it is assumed that the command to set the narrowing condition for narrowing down the plurality of pieces of production factor information D1 set for the production factors PF of the feeder 24F and the suction nozzle 2511 is input via the operating unit 143. In this case, the calculation unit 1452 outputs the specified normal suction rate data set DS1, the normal loading rate data set DS2, and the suction level data set DS3 associated with the production factor information D1 that satisfies the narrowing condition among the plurality of pieces of production factor information D1. This allows the data sets DS1, DS2, and DS3 to be referred to when the data generating unit 1453 generates the predicted normal suction rate data DP1, the predicted normal loading rate data DP2, and the predicted suction level data DV to be narrowed down according to the narrowing condition. In this case, based on the specified normal suction rate data set DS1, the normal loading rate data set DS2, and the suction level data set DS3 associated with the production factor information D1 that satisfies the narrowing condition, the data generating unit 1453 generates the predicted normal suction rate data DP1, the predicted normal loading rate data DP2, and the predicted suction level data DV.

The display control unit 1454 controls the display unit 142 to display the predicted normal suction rate data DP1, the predicted normal loading rate data DP2, and the predicted suction level data DV generated by the data generating unit 1453 corresponding to the specified data sets DS1, DS2, and DS3. In this case, the operator can predict the future error (abnormality) generating status subsequent to the current time point TP while paying attention to the production factor information D1 that satisfies the narrowing condition.

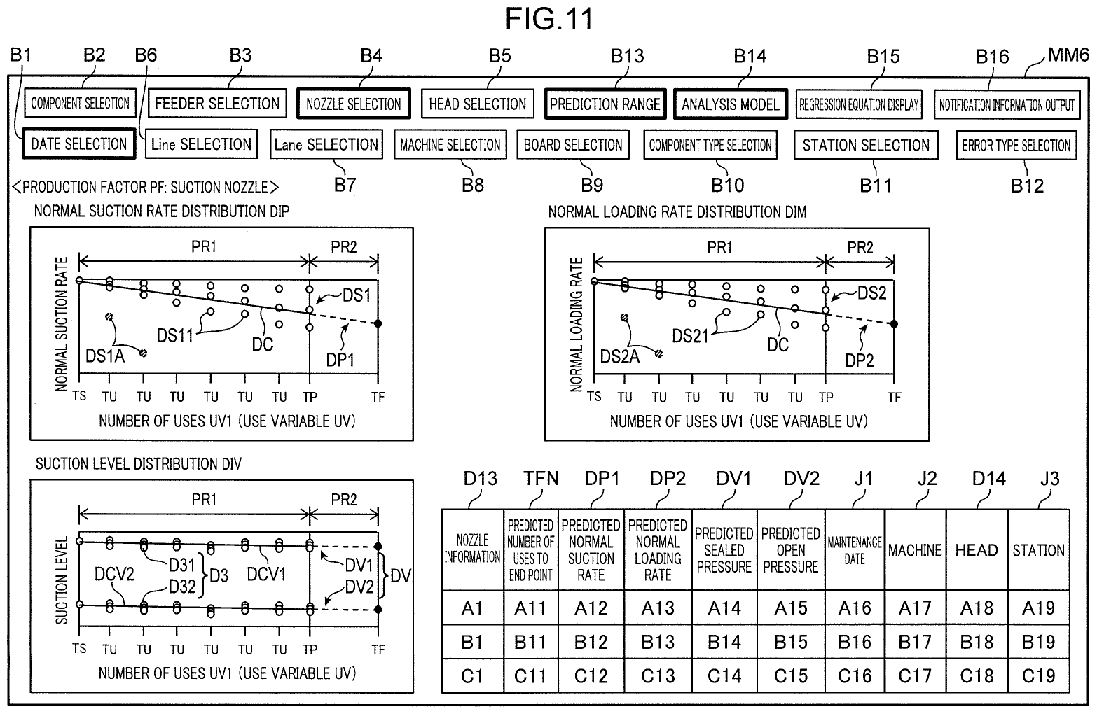

Next, as shown in FIG. 11, with the normal suction rate distribution DIP displayed in the display screen MM6 of the display unit 142, it is assumed that a command to select unique normal suction rate data DS1A from the data group of the normal suction rate data DS11 that constitutes the normal suction rate distribution DIP is input via the operating unit 143. In this case, the display control unit 1454 makes the data group of the unique data set that is the normal suction rate data set DS1 to which the unique normal suction rate data DS1A belongs invisible. Then, the data generating unit 1453 generates the predicted normal suction rate data DP1 based on the remaining normal suction rate data set DS1 after removing the unique data set from the plurality of normal suction rate data sets DS1 corresponding to the production factors PF. Based on such predicted normal suction rate data DP1 that corresponds to the remaining normal suction rate data set DS1 after removing the unique data set, the operator can predict the future suction error (abnormality) generating status subsequent to the current time point TP with the unique normal suction rate data DS1A excluded.

Similarly, with the normal loading rate distribution DIM displayed in the display screen MM6 of the display unit 142, it is assumed that a command to select unique normal loading rate data DS2A from the data group of the normal loading rate data DS21 that constitutes the normal loading rate distribution DIM is input via the operating unit 143. In this case, the display control unit 1454 makes the data group of the unique data set that is the normal loading rate data set DS2 to which the unique normal loading rate data DS2A belongs invisible. Then, the data generating unit 1453 generates the predicted normal loading rate data DP2 based on the remaining normal loading rate data set DS2 after removing the unique data set from the plurality of normal loading rate data sets DS2 corresponding to the production factors PF. Based on such predicted normal loading rate data DP2 that corresponds to the remaining normal loading rate data set DS2 after removing the unique data set, the operator can predict the future loading error (abnormality) generating status subsequent to the current time point TP with the unique normal loading rate data DS2A excluded.

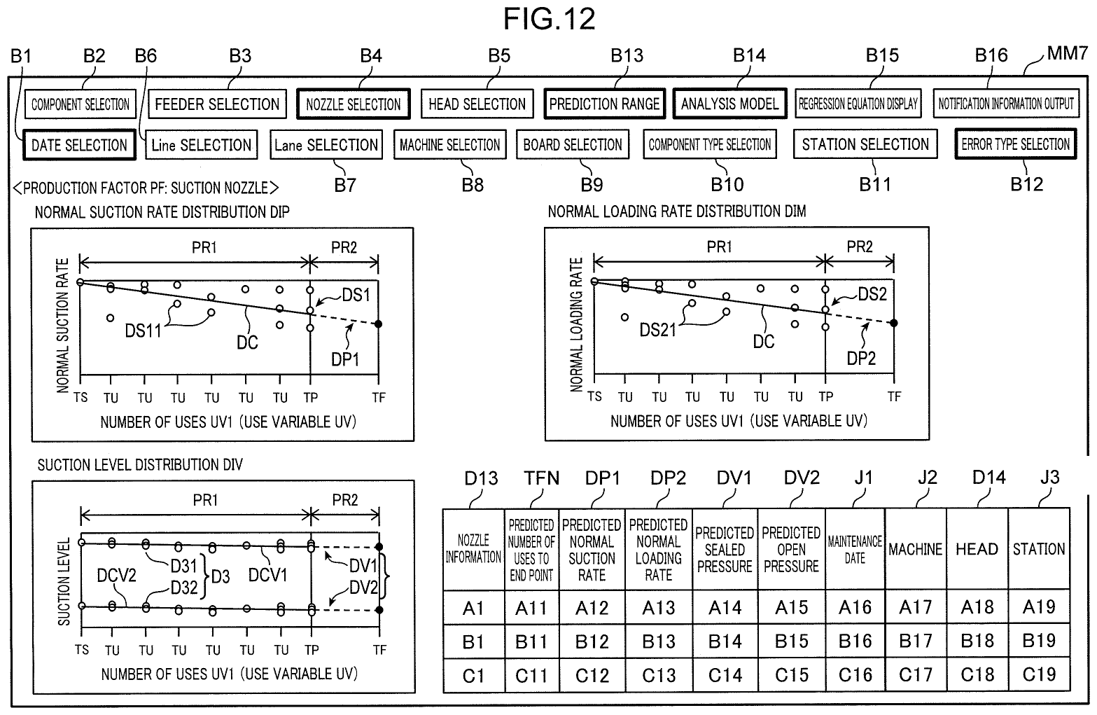

As described above, as the suction error regarding the error of the suction state of the component 24P by the suction nozzle 2511, there is a plurality of types of errors such as the component fall error, the suction position offset error, and the component posture error. As shown in FIG. 12, with the normal suction rate distribution DIP displayed in the display screen MM7 of the display unit 142, it is assumed that the error type selection command to select the error type from the plurality of types of suction errors is input via the operating unit 143 by the operation of the error type selection region B12 set in the display screen MM7. In this case, the display control unit 1454 controls the display unit 142 to display distribution of the data group of specified error type corresponding data that is the normal suction rate data DS11 to which the suction error type information D211 (see FIG. 5) corresponding to the error type indicated by the error type selection command is added, as the normal suction rate distribution DIP. Then, the data generating unit 1453 generates the predicted normal suction rate data DP1 based on the data group of the specified error type corresponding data. Based on such predicted normal suction rate data DP1 corresponding to the data group of the specified error type corresponding data, the operator can predict the future suction error (abnormality) generating status subsequent to the current time point TP while paying attention to the error type of the suction error indicated by the error type selection command.

Similarly, as the loading error regarding the error of the loading state of the component 24P on the component loading board PPA, there is a plurality of types of errors such as the component posture error, the loading position offset error, the coplanarity error, the lead pitch error, the lead width error, and the number of leads error. As shown in FIG. 12, with the normal loading rate distribution DIM displayed in the display screen MM7 of the display unit 142, it is assumed that the error type selection command to select the error type from the plurality of types of loading error by the operation of the error type selection region B12 set in the display screen MM7 is input via the operating unit 143. In this case, the display control unit 1454 controls the display unit 142 to display distribution of the data group of specified error type corresponding data that is the normal loading rate data DS21 to which the loading error type information D221 (see FIG. 5) corresponding to the error type indicated by the error type selection command is added, as the normal loading rate distribution DIM. Then, the data generating unit 1453 generates the predicted normal loading rate data DP2 based on the data group of the specified error type corresponding data. Based on such predicted normal loading rate data DP2 corresponding to the data group of the specified error type corresponding data, the operator can predict the future loading error (abnormality) generating status subsequent to the current time point TP while paying attention to the error type of the loading error indicated by the error type selection command.

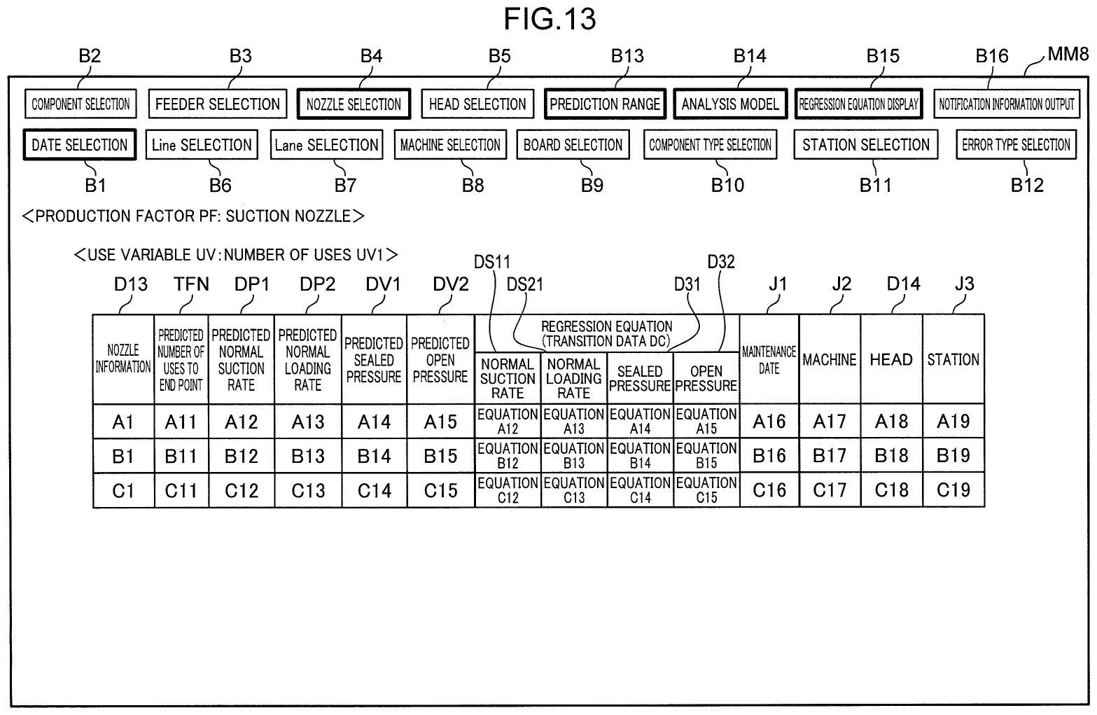

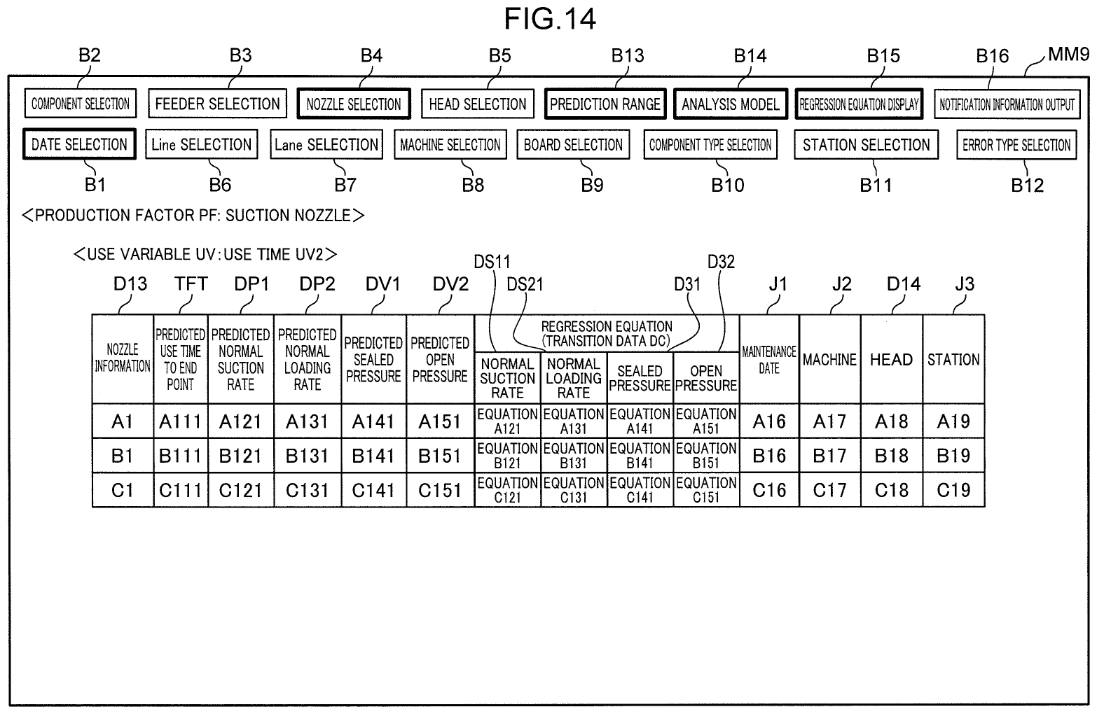

Next, as shown in FIGS. 13 and 14, it is assumed that a command to cause the display unit 142 to display the regression equation determined by the data generating unit 1453 is input via the operating unit 143 by the operation of the regression equation display setting region B15 set in the display screens MM8 and MM9 of the display unit 142. In this case, the display control unit 1454 controls the display unit 142 to display the regression equation generated by the data generating unit 1453 corresponding to the prediction data DP1, DP2, DV1, and DV2 when displaying the predicted normal suction rate data DP1, the predicted normal loading rate data DP2, the predicted sealed pressure data DV1, and the predicted open pressure data DV2 as tabular information.

FIG. 13 shows an example where the use variable setting command to set the number of uses UV1 as the use variable UV is input into the prediction range setting region B13, and a regression equation display command is input into the regression equation display setting region B15. In this case, the regression equations with the number of uses UV1 as an explanatory variable and the normal suction rate data DS11, the normal loading rate data DS21, the sealed pressure data D31, and the open pressure data D32 as dependent variables are displayed in the display screen MM8. By substituting a desired value as the number of uses UV1 of the explanatory variable in each regression equation, the predicted normal suction rate data DP1, the predicted normal loading rate data DP2, the predicted sealed pressure data DV1, and the predicted open pressure data DV2 corresponding to the desired value can be calculated.

FIG. 14 shows an example where the use variable setting command to set the use time UV2 as the use variable UV is input into the prediction range setting region B13, and a regression equation display command is input into the regression equation display setting region B15. In this case, the regression equations with the use time UV2 as an explanatory variable and the normal suction rate data DS11, the normal loading rate data DS21, the sealed pressure data D31, and the open pressure data D32 as dependent variables are displayed in the display screen MM9. By substituting a desired value as the use time UV2 of the explanatory variable in each regression equation, the predicted normal suction rate data DP1, the predicted normal loading rate data DP2, the predicted sealed pressure data DV1, and the predicted open pressure data DV2 corresponding to the desired value can be calculated.

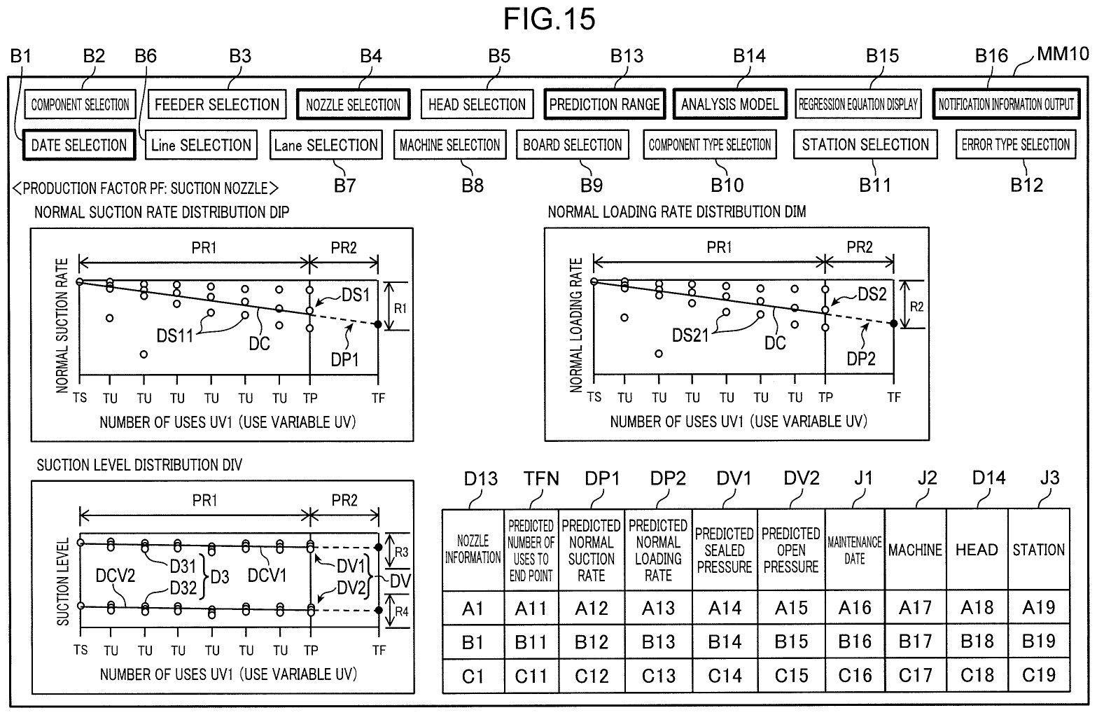

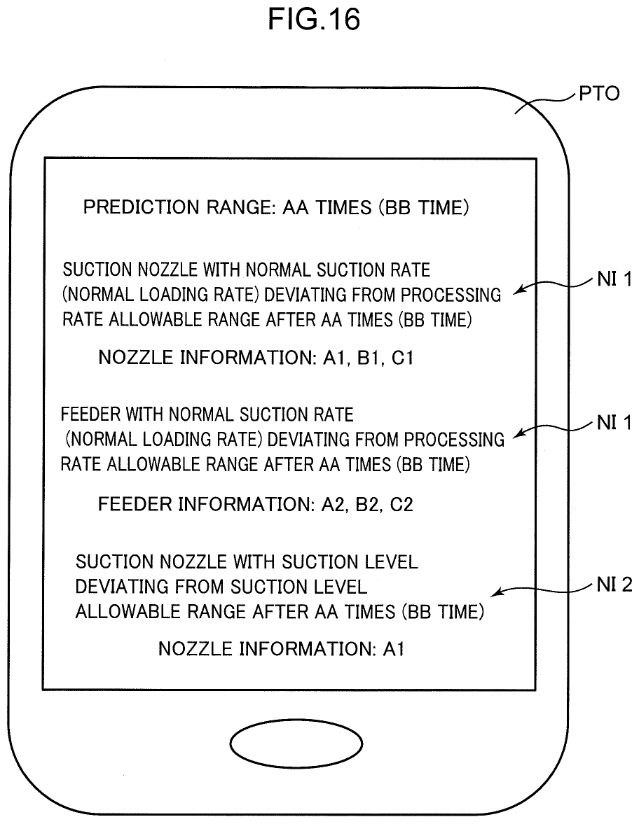

Next, as shown in FIG. 15, it is assumed that a command to cause the data generating unit 1453 to output the notification information is input via the operating unit 143 by the operation of the notification information output setting region B16 set in the display screen MM10 of the display unit 142. Note that the notification information output from the data generating unit 1453 is displayed, for example, on a portable terminal PTO carried by the operator, as shown in FIG. 16.

The data generating unit 1453 determines whether the predicted normal suction rate data DP1 deviates from a preset suction rate allowable range R1, and determines whether the predicted normal loading rate data DP2 deviates from a preset loading rate allowable range R2. When the predicted normal suction rate data DP1 deviates from the suction rate allowable range R1, or when the predicted normal loading rate data DP2 deviates from the loading rate allowable range R2, the data generating unit 1453 outputs processing rate notification information NI1 to notify the deviation. The processing rate notification information NI1 includes information such as the feeder information D12 and the nozzle information D13 that constitute the production factor information D1 associated with the predicted normal suction rate data DP1 that deviates from the suction rate allowable range R1, and the predicted normal loading rate data DP2 that deviates from the loading rate allowable range R2. The processing rate notification information NI1 output from the data generating unit 1453 is displayed on the portable terminal PTO carried by the operator. This allows the operator to accurately determine the maintenance timing of the production factors PF such as the feeder 24F and the suction nozzle 2511, and the like.

The data generating unit 1453 determines whether the predicted suction level data DV deviates from the preset suction level allowable range (holding level allowable range). The suction level allowable range includes a sealed pressure allowable range R3 corresponding to the predicted sealed pressure data DV1 and an open pressure allowable range R4 corresponding to the predicted open pressure data DV2. That is, the data generating unit 1453 determines whether the predicted sealed pressure data DV1 deviates from the sealed pressure allowable range R3, and determines whether the predicted open pressure data DV2 deviates from the open pressure allowable range R4. When the predicted sealed pressure data DV1 deviates from the sealed pressure allowable range R3, or when the predicted open pressure data DV2 deviates from the open pressure allowable range R4, the data generating unit 1453 outputs suction level notification information NI2 to notify the deviation. The suction level notification information NI2 includes information such as the nozzle information D13 that constitutes the production factor information D1 associated with the predicted sealed pressure data DV1 that deviates from the sealed pressure allowable range R3, and the predicted open pressure data DV2 that deviates from the open pressure allowable range R4, and the like. The suction level notification information NI2 output from the data generating unit 1453 is displayed on the portable terminal PTO carried by the operator. This allows the operator to accurately determine the maintenance timing of the negative pressure generation device and the like connected to the suction nozzle 2511, and the like.

Note that the above-described specific embodiment mainly includes the disclosure having the following configurations.

A component mounting system according to one aspect of the present disclosure includes a mounting machine that produces a component loading board on which a component is loaded, and a management device that manages the production of the component loading board in the mounting machine. The mounting machine includes a feeder that supplies the component and a holding member that holds the component supplied by the feeder and obtains the component loading board by loading the held component on a board. The management device includes a storage unit, a calculation unit, a data generating unit, an operating unit, and a display unit. The storage unit is configured to accumulate and store, for each use of production factors, management data in which processing state data indicating whether a processing state indicated by at least one of a holding state of the component by the holding member and a loading state of the component on the component loading board is normal or abnormal is associated with each piece of production factor information for identifying the production factors indicating the feeder and the holding member used in the production of the component loading board. The calculation unit is configured to calculate normal processing rate data indicating a ratio of a number of uses when the processing state is normal to a number of uses of the production factors based on a data group of the management data within a period from a prescribed time point to a current time point for each of use time points when the production factors are used within the period, and output a normal processing rate data set with a data group of the normal processing rate data for each of the use time points as one set, in association with each piece of the production factor information. The data generating unit is configured to generate predicted normal processing rate data indicating a predicted value of the normal processing rate data subsequent to the current time point according to a change in a use variable indicated by at least one of use time and the number of uses of the production factors in association with each piece of the production factor information, based on the normal processing rate data set. Various commands are input into the operating unit. The display unit is configured to display the predicted normal processing rate data associated with the production factor information corresponding to each of the production factors indicated by a factor selection command when the factor selection command to select one of the production factors is input via the operating unit.

This component mounting system is provided with the management device for managing production of the component loading board in the mounting machine. In this management device, based on the data group of the management data stored in the storage unit, the calculation unit calculates the normal processing rate data for each use time point when each production factor is used within the period from the prescribed time point to the current time point. The calculation unit outputs the normal processing rate data set with the data group of the normal processing rate data for each of the use time points as one set in association with each piece of the production factor information for identifying each production factor. In the management device, the data generating unit generates the predicted normal processing rate data indicating the predicted value of the normal processing rate data subsequent to the current time point according to the change in the use variable indicated by at least one of the use time and the number of uses of the production factors in association with each piece of the production factor information, based on the normal processing rate data set.

The predicted normal processing rate data generated by the data generating unit is data indicating the predicted value of the normal processing rate data indicating the ratio of the number of uses when the processing state is normal to the number of uses of the production factors, subsequent to the current time point according to the change in the use variable. The predicted normal processing rate data is displayed in the display unit. This makes it possible to predict the future error (abnormality) generating status subsequent to the current time point according to the use of the production factor used in the production of the component loading board based on the predicted normal processing rate data. Therefore, it becomes possible to predict the frequency and timing of maintenance for the production factor in order to suppress the error generation in the future subsequent to the current time point, and to execute maintenance accurately.

In the component mounting system, the calculation unit is configured, when the plurality of pieces of production factor information is set for the production factors, to output a plurality of the normal processing rate data sets associated with the plurality of pieces of production factor information. In this case, the data generating unit is configured to generate the predicted normal processing rate data common to the plurality of normal processing rate data sets.

The plurality of pieces of production factor information may be set for each production factor used in the production of the component loading board. That is, in the production of the component loading board, when the plurality of feeders and the plurality of holding members are used, the plurality of pieces of production factor information is set for each production factor. In this case, the calculation unit outputs the plurality of normal processing rate data sets associated with each of the plurality of pieces of production factor information. Then, the data generating unit generates the predicted normal processing rate data common to the plurality of normal processing rate data sets. Based on such predicted normal processing rate data that is common to the plurality of normal processing rate data sets associated with the plurality of pieces of production factor information, it is possible to predict the future error (abnormality) generating status subsequent to the current time point with the plurality of feeders and the plurality of holding members corresponding to the plurality of pieces of production factor information as one group.

In the component mounting system, the calculation unit is configured, when a command to set a narrowing condition for narrowing down the plurality of pieces of production factor information set for the production factors is input via the operating unit, to output the specified normal processing rate data set associated with the production factor information that satisfies the narrowing condition among the plurality of pieces of production factor information. In this case, the data generating unit is configured to generate the predicted normal processing rate data based on the specified normal processing rate data set.

In this aspect, when the command to set the narrowing condition for narrowing the plurality of pieces of production factor information set for the production factors is input via the operating unit, the calculation unit outputs the specified normal processing rate data set associated with the production factor information that satisfies the narrowing condition. This allows the normal processing rate data set the data generating unit refers to when generating the predicted normal processing rate data to be narrowed down according to the narrowing condition. In this case, based on the specified normal processing rate data set associated with the production factor information that satisfies the narrowing condition, the data generating unit generates the predicted normal processing rate data. Based on such predicted normal processing rate data corresponding to the specified normal processing rate data set, it becomes possible to predict the future error (abnormality) generating status subsequent to the current time point while paying attention to the production factor information that satisfies the narrowing condition.

In the component mounting system, the data generating unit is configured to generate transition data indicating transition of the normal processing rate data according to the change in the use variable within the period based on the normal processing rate data set, and extend the transition data to the current time point and beyond regarding the use variable to generate the predicted normal processing rate data.

In this aspect, the data generating unit generates the transition data indicating the transition of the normal processing rate data according to the change in the use variable within the period from the prescribed time point to the current time point. Then, the data generating unit can generate the predicted normal processing rate data by extending the transition data to the current time point and beyond regarding the use variable.

In the component mounting system, the data generating unit is configured to determine a regression equation through regression analysis with the use variable as an explanatory variable and the normal processing rate data as a dependent variable, generates a regression line based on the regression equation as the transition data, and extend the regression line to the current time point and beyond regarding the use variable to generate the predicted normal processing rate data.

In this aspect, the data generating unit determines the regression equation through regression analysis with the use variable as an explanatory variable and the normal processing rate data as a dependent variable, and generates the regression line as the transition data based on the regression equation. Then, the data generating unit can generate the predicted normal processing rate data by extending the regression line to the current time point and beyond regarding the use variable.

In the component mounting system, the display unit is configured to display normal processing rate distribution indicating distribution of the data group of the normal processing rate data indicated by the plurality of normal processing rate data sets output from the calculation unit simultaneously with the predicted normal processing rate data.

In this aspect, the normal processing rate distribution indicating the distribution of the data group of the normal processing rate data and the predicted normal processing rate data are displayed simultaneously in the display unit. This makes it possible to predict the future error (abnormality) generating status subsequent to the current time point based on the predicted normal processing rate data while checking the distribution of the normal processing rate data within the period from the prescribed time point to the current time point.

In the component mounting system, when a command to select a unique normal processing rate data from the data group of the normal processing rate data that constitutes the normal processing rate distribution is input via the operating unit with the normal processing rate distribution displayed, the display unit is configured to make a data group of a unique data set that is the normal processing rate data set to which the unique normal processing rate data belongs invisible. In this case, the data generating unit is configured to generate the predicted normal processing rate data based on a remaining normal processing rate data set after removing the unique data set from the plurality of normal processing rate data sets.

In this aspect, when the command to select the unique normal processing rate data from the data group of the normal processing rate data that constitutes the normal processing rate distribution displayed in the display unit is input via the operating unit, the display unit makes the data group of the unique data set to which the unique normal processing rate data belongs invisible. In this case, the data generating unit generates the predicted normal processing rate data based on the remaining normal processing rate data set after removing the unique data set from the plurality of normal processing rate data sets associated with the plurality of pieces of production factor information. Based on such predicted normal processing rate data that corresponds to the remaining normal processing rate data set after removing the unique data set, it is possible to predict the future error (abnormality) generating status subsequent to the current time point with the unique normal processing rate data excluded.

In the component mounting system, the storage unit is configured to store the management data including the processing state data to which error type information regarding an error type indicating an abnormality in the processing state is added. The calculation unit is configured to output the normal processing rate data set indicated by the data group of the normal processing rate data with the error type information added. When an error type selection command to select the error type of the processing state is input via the operating unit with the normal processing rate distribution displayed, the display unit is configured to display distribution of a data group of specified error type corresponding data that is the normal processing rate data to which the error type information corresponding to the error type indicated by the error type selection command is added as the normal processing rate distribution. In this case, the data generating unit is configured to generate the predicted normal processing rate data based on the data group of the specified error type corresponding data.

The error indicating abnormality in the processing state includes a holding error regarding an error in the holding state of the component by the holding member and a loading error regarding an error in the loading state of the component on the component loading board. As the holding error, there is a plurality of types of holding error about the component fall indicating the component fall from the holding member, the component holding position offset from the holding member, the component holding posture with respect to the holding member, and the like. As the loading error, there is a plurality of types of loading error about the loading posture or loading position offset of the component on the component loading board, coplanarity of the component loading board, the lead pitch, the lead width, and the number of leads of the component on the component loading board, and the like.

When such an error type selection command to select the error type from among the plurality of error types is input via the operating unit, the display unit displays distribution of the data group of specified error type corresponding data that is the normal processing rate data to which the error type information corresponding to the error type indicated by the error type selection command is added as the normal processing rate distribution. In this case, the data generating unit generates the predicted normal processing rate data based on the data group of the specified error type corresponding data. Based on such predicted normal processing rate data corresponding to the data group of the specified error type corresponding data, it is possible to predict the future error (abnormality) generating status subsequent to the current time point while paying attention to the error type indicated by the error type selection command.

In the component mounting system, when the predicted normal processing rate data deviates from a preset processing rate allowable range, the data generating unit is configured to output information to notify the deviation.

In this aspect, when the predicted normal processing rate data deviates from the processing rate allowable range, the data generating unit outputs information to notify the deviation. This makes it possible to accurately notify the maintenance timing of the production factors such as the feeder and the holding member, and the like.

In the component mounting system, the storage unit is configured to accumulate and store data further associated with holding level data indicating a holding level of the component by the holding member as the management data. The calculation unit is configured to output a holding level data set with a data group of the holding level data for each of the use time points as one set in association with each piece of the production factor information. Then, the data generating unit is configured to generate predicted holding level data indicating a predicted value of the holding level data subsequent to the current time point according to the change in the use variable in association with each piece of the production factor information based on the holding level data set. In this case, the display unit is configured to display the predicted holding level data associated with the production factor information corresponding to the production factor indicated by the factor selection command simultaneously with the predicted normal processing rate data.

In this aspect, the predicted holding level data indicating the predicted value of the holding level data regarding the holding level of the component by the holding member subsequent to the current time point is displayed simultaneously with the predicted normal processing rate data in the display unit. This makes it possible to predict the future error (abnormality) generating status subsequent to the current time point based on the predicted normal processing rate data and the predicted holding level data.

In the component mounting system, when the predicted holding level data deviates from a preset holding level allowable range, the data generating unit is configured to output information to notify the deviation.

In this aspect, when the predicted holding level data deviates from the holding level allowable range, the data generating unit outputs information to notify the deviation. This makes it possible to accurately notify the maintenance timing of a device connected to the holding member for adjusting the holding level, and the like.

As described above, the present disclosure can provide a component mounting system capable of predicting the future error generating status subsequent to the current time point according to the use of the production factors used in the production of the component loading board.

1. A component mounting system comprising:
a mounting machine that configured to produce a component loading board on which a component is loaded; and
a management device configured to manage the production of the component loading board in the mounting machine,
wherein the mounting machine includes:
a feeder configured to supply the component; and
a holding member configured to hold the component supplied by the feeder and obtains the component loading board by loading the held component on a board,
the management device includes:
a storage configured to accumulate and store, for each use of production factors, management data in which processing state data indicating whether a processing state indicated by at least one of a holding state of the component by the holding member and a loading state of the component on the component loading board is normal or abnormal is associated with each piece of production factor information for identifying the production factors indicating the feeder and the holding member used in the production of the component loading board;
a processor configured to
calculate normal processing rate data indicating a ratio of a number of uses when the processing state is normal to a number of uses of the production factors based on a data group of the management data within a period from a prescribed time point to a current time point for each of use time points when the production factors are used within the period, and output a normal processing rate data set with a data group of the normal processing rate data for each of the use time points as one set, in association with each piece of the production factor information; and
generate predicted normal processing rate data indicating a predicted value of the normal processing rate data subsequent to the current time point according to a change in a use variable indicated by at least one of use time and the number of uses of the production factors in association with each piece of the production factor information, based on the normal processing rate data set;
an operating unit configured to receive input of various commands; and
a display configured to display the predicted normal processing rate data associated with the production factor information corresponding to each of the production factors indicated by a factor selection command when the factor selection command to select one of the production factors is input via the operating unit.

2. The component mounting system according to claim 1, wherein
the processor is configured, when a plurality of pieces of production factor information is set for the production factors, to output a plurality of the normal processing rate data sets associated with the plurality of pieces of production factor information, and
the processor is configured to generate the predicted normal processing rate data common to the plurality of normal processing rate data sets.

3. The component mounting system according to claim 2, wherein
the processor is configured, when a command to set a narrowing condition for narrowing down the plurality of pieces of production factor information set for the production factors is input via the operating unit, to output the specified normal processing rate data set associated with the production factor information that satisfies the narrowing condition among the plurality of pieces of production factor information, and
the processor is configured to generate the predicted normal processing rate data based on the specified normal processing rate data set.

4. The component mounting system according to claim 2, wherein the processor is configured to generate transition data indicating transition of the normal processing rate data according to the change in the use variable within the period based on the normal processing rate data set, and extend the transition data to the current time point and beyond regarding the use variable to generate the predicted normal processing rate data.

5. The component mounting system according to claim 4, wherein the processor is configured to determine a regression equation through regression analysis with the use variable as an explanatory variable and the normal processing rate data as a dependent variable, generates a regression line based on the regression equation as the transition data, and extend the regression line to the current time point and beyond regarding the use variable to generate the predicted normal processing rate data.

6. The component mounting system according to claim 2, wherein the display is configured to display normal processing rate distribution indicating distribution of the data group of the normal processing rate data indicated by the plurality of normal processing rate data sets output from the processor simultaneously with the predicted normal processing rate data.

7. The component mounting system according to claim 6, wherein
when a command to select a unique normal processing rate data from the data group of the normal processing rate data that indicates the normal processing rate distribution is input via the operating unit with the normal processing rate distribution displayed, the display is configured to make a data group of a unique data set that is the normal processing rate data set to which the unique normal processing rate data belongs invisible, and
the processor is configured to generate the predicted normal processing rate data based on a remaining normal processing rate data set after removing the unique data set from the plurality of normal processing rate data sets.

8. The component mounting system according to claim 6, wherein
the storage is configured to store the management data including the processing state data to which error type information regarding an error type indicating an abnormality in the processing state is added,
the processor is configured to output the normal processing rate data set indicated by the data group of the normal processing rate data with the error type information added,
when an error type selection command to select the error type of the processing state is input via the operating unit with the normal processing rate distribution displayed, the display is configured to display distribution of a data group of specified error type corresponding data that is the normal processing rate data to which the error type information corresponding to the error type indicated by the error type selection command is added as the normal processing rate distribution, and
the processor is configured to generate the predicted normal processing rate data based on the data group of the specified error type corresponding data.

9. The component mounting system according to claim 1, wherein when the predicted normal processing rate data deviates from a preset processing rate allowable range, the processor is configured to output information to notify the deviation.

10. The component mounting system according to claim 1, wherein
the storage is configured to accumulate and store data further associated with holding level data indicating a holding level of the component by the holding member as the management data,
the processor is configured to output a holding level data set with a data group of the holding level data for each of the use time points as one set in association with each piece of the production factor information,
the processor is configured to generate predicted holding level data indicating a predicted value of the holding level data subsequent to the current time point according to the change in the use variable in association with each piece of the production factor information based on the holding level data set, and
the display is configured to display the predicted holding level data associated with the production factor information corresponding to the production factor indicated by the factor selection command simultaneously with the predicted normal processing rate data.

11. The component mounting system according to claim 10, wherein when the predicted holding level data deviates from a preset holding level allowable range, the processor is configured to output information to notify the deviation.

12. The component mounting system according to claim 3, wherein the processor is configured to generate transition data indicating transition of the normal processing rate data according to the change in the use variable within the period based on the normal processing rate data set, and extend the transition data to the current time point and beyond regarding the use variable to generate the predicted normal processing rate data.

13. The component mounting system according to claim 3, wherein the display is configured to display normal processing rate distribution indicating distribution of the data group of the normal processing rate data indicated by the plurality of normal processing rate data sets output from the processor simultaneously with the predicted normal processing rate data.

14. The component mounting system according to claim 4, wherein the display is configured to display normal processing rate distribution indicating distribution of the data group of the normal processing rate data indicated by the plurality of normal processing rate data sets output from the processor simultaneously with the predicted normal processing rate data.

15. The component mounting system according to claim 5, wherein the display is configured to display normal processing rate distribution indicating distribution of the data group of the normal processing rate data indicated by the plurality of normal processing rate data sets output from the processor simultaneously with the predicted normal processing rate data.

16. The component mounting system according to claim 7, wherein
the storage is configured to store the management data including the processing state data to which error type information regarding an error type indicating an abnormality in the processing state is added,
the processor is configured to output the normal processing rate data set indicated by the data group of the normal processing rate data with the error type information added,
when an error type selection command to select the error type of the processing state is input via the operating unit with the normal processing rate distribution displayed, the display is configured to display distribution of a data group of specified error type corresponding data that is the normal processing rate data to which the error type information corresponding to the error type indicated by the error type selection command is added as the normal processing rate distribution, and
the processor is configured to generate the predicted normal processing rate data based on the data group of the specified error type corresponding data.
